(19) United States
(12) Patent Application Publication
(10) Pub. No.: US 2025/0372394 A1
(43) Pub. Date: Dec. 4, 2025

(54) SUBSTRATE PROCESSING METHOD AND SUBSTRATE PROCESSING APPARATUS

(71) Applicant: Tokyo Electron Limited, Tokyo (JP)

(72) Inventors: Xiaolong LI, Nirasaki City (JP); Kazuya DOBASHI, Nirasaki City (JP); Hiroki MAEHARA, Tokyo (JP)

(21) Appl. No.: 19/219,236

(22) Filed: May 27, 2025

(30) Foreign Application Priority Data
Jun. 4, 2024 (JP) 2024-090421

(51) Int. Cl. H01L 21/311; C23C 14/08; C23C 14/34; C23C 14/58; C23C 16/40; C23C 16/455; C23C 16/52; C23C 16/56; H01L 21/02; H01L 21/768

(52) U.S. Cl. CPC H01L 21/31144; C23C 14/08; C23C 14/345; C23C 14/5873; C23C 16/40; C23C 16/45544; C23C 16/52; C23C 16/56; H01L 21/0206; H01L 21/76802; H01L 21/76877

(57) ABSTRACT

A substrate processing method includes: providing a substrate having first and second surfaces; forming a dielectric film on the first surface; forming a metal oxide film including one or two or more metal elements with a predetermined composition on the dielectric film; subsequently, forming a resist-related first film in which a first pattern is formed; subsequently, etching the first hard mask to form a recess corresponding to the first pattern in the metal oxide film; etching the dielectric film to form the recess corresponding to the first pattern in the dielectric film; subsequently, cleaning the substrate to remove the metal oxide film; embedding a metal in the recess formed in the dielectric film; and planarizing the metal.

### CROSS-REFERENCE TO RELATED APPLICATION

This application is based upon and claims the benefit of priority from Japanese Patent Application No. 2024-090421, filed on Jun. 4, 2024, the entire contents of which are incorporated herein by reference.

### TECHNICAL FIELD

The present disclosure relates to a substrate processing method and a substrate processing apparatus.

### BACKGROUND

For example, Patent Document 1 discloses, a method of forming a dual damascene structure includes forming a stacked structure of an organic insulating film as a hard mask and a metal oxide on an inorganic insulating film, and patterning and etching the stacked structure, in which at least one type of metal oxide among B, Al, Ga, In, Tl, Si, Ge, Sn, Pb, Ti, Zr, Hf, V, Nb, Ta, Cr, Mo, W, Mn, Zn, Cd, P, As, Sb, Bi, and Ce is used as a metal oxide film.

Patent Document 2 discloses a method of dry-etching an oxide semiconductor film including at least In, Ga, and Zn, in which the oxide semiconductor film is etched in a gas atmosphere including hydrocarbon.

Patent Document 3 discloses a substrate processing method using a hard mask having a high selectivity with respect to a processing target made of oxide containing one or two or more gallium, indium, and zinc, which is capable of implementing a reduction in film thickness.

### PRIOR ART DOCUMENTS

### Patent Documents

Patent Document 1: Japanese Patent Laid-Open Publication No. 2002-299441
Patent Document 2: Japanese Patent Laid-Open Publication No. 2007-335505
Patent Document 3: Japanese Patent Laid-Open Publication No. 2023-127329

### SUMMARY

According to one embodiment of the present disclosure, there is provided a substrate processing method including: an operation (A) of providing a substrate having a first surface and a second surface opposite the first surface; an operation (B) of forming a dielectric film on the first surface; an operation (C) of forming a metal oxide film as a first hard mask including one or two or more metal elements with a predetermined composition on the dielectric film, wherein the metal oxide film includes no crystalline film; after the operation (C), an operation (F) of forming a resist-related first film in which a first pattern is formed; after the operation (F), an operation (G) of etching the first hard mask to form a recess corresponding to the first pattern in the first hard mask; an operation (H) of etching the dielectric film to form the recess corresponding to the first pattern in the dielectric film; after the operation (H), an operation (I) of cleaning the substrate to remove the first hard mask; an operation (J) of embedding a metal in the recess formed in the dielectric film; and an operation (K) of planarizing the metal.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating an example of a substrate processing method according to a first embodiment.

FIG. 2A is a schematic cross-sectional view illustrating operations of forming a damascene structure.

FIG. 2B is a schematic cross-sectional view illustrating operations of forming the damascene structure.

FIG. 2C is a schematic cross-sectional view illustrating operations of forming the damascene structure.

FIG. 3 is a view illustrating a composition ratio of metal elements of a first hard mask.

FIG. 4 is a graph illustrating an example of crystallinity of the first hard mask.

FIG. 5 is a time chart illustrating an example of an etching process performed on the first hard mask.

FIG. 6 is a view illustrating an example of results obtained by performing a cyclic etching process on the first hard mask.

FIG. 7 is a graph illustrating an example of results obtained by performing a cleaning process on a front surface of the substrate.

FIG. 8 is a graph illustrating another example of results obtained by performing the cleaning process on the front surface of the substrate of a cleaning process result of the substrate surface.

FIG. 9 is a flowchart illustrating an example of a substrate processing method according to a second embodiment.

FIG. 10A is a schematic cross-sectional view illustrating operations of forming a dual damascene structure.

FIG. 10B is a schematic cross-sectional view illustrating operations of forming the dual damascene structure.

FIG. 11 is a view illustrating an example of roughness in operations of the substrate processing method.

FIG. 12 is a view schematically illustrating a configuration of a film forming apparatus according to an embodiment.

FIG. 13 is a view schematically illustrating a configuration of a film forming apparatus according to an embodiment.

FIG. 14 is a view schematically illustrating a configuration of an etching apparatus according to an embodiment.

FIG. 15 is a view schematically illustrating a configuration of a cleaning apparatus according to an embodiment.

FIG. 16 is a view illustrating a configuration of a cleaning apparatus according to a modification.

FIG. 17 is a view schematically illustrating a configuration of a substrate processing system according to an embodiment.

### DETAILED DESCRIPTION

Hereinafter, embodiments of a substrate processing method and a substrate processing apparatus of the present disclosure will be described in detail with reference to the drawings. In addition, the substrate processing method and the substrate processing apparatus according to the present disclosure are not limited to these embodiments. In the following embodiments, configurations or processing contents of the present disclosure may be appropriately combined with each other to the extent that they are not contradictory. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In addition, the drawings referred herein are schematic for the sake of convenience in description. Therefore, details thereof will be omitted. Further, dimension ratios do not necessarily coincide with actual dimension ratios.

Along with high integration and high speed of semiconductor devices, a reduction in capacity between wirings and a reduction in resistance of a metal wiring have been promoted. The resistance of the metal wiring not only depends on resistivity of a metal material but also depends largely on roughness of the metal wiring itself. When the roughness of the metal wiring is degraded, electromagnetic waves are highly likely to be reflected on a sidewall of the wiring, which reduces propagation efficiency of electromagnetic signals and appears as an increase in resistance value of the metal wiring.

In recent years, a damascene structure or a dual damascene structure has been employed in a metal wiring process for semiconductors. In a method of forming such a structure, processes which may involve roughness of a metal wiring are mainly an etching process and a cleaning process for a wiring pattern. In the etching process, a resist mask or a metal mask of titanium nitride (TiN) may be used to etch the wiring pattern. In the process of etching the wiring pattern using the resist mask, in the case of a fine region in which a pitch of the wiring pattern is 60 nm or less, selectivity of the resist mask with respect to a wiring layer is not sufficient. As a result, the resist mask may be lost during the etching process. In order to prevent the loss of the resist mask, the resist mask having a thick thickness may be formed. In this case, the resist mask may collapse due to a high aspect ratio, or adjacent resist masks may collapse with respect to each other. As a result, kissing which deteriorates roughness is prone to occur. In view of the foregoing, the metal mask tends to be used in the fine region. In particular, a metal mask made of TiN is mainly used.

However, even when the wiring pattern is etched using the metal mask made of TiN, the metal mask made of TiN, which has a thick thickness and poor selectivity with respect to the wiring pattern, is used. As a result, wiggling in which a sidewall of the wiring pattern undulates due to stress of the metal mask may occur. This may affect the roughness of the metal wiring. Further, the metal mask made of TiN has a low transmittance, which makes it difficult to align a multilayer wiring. This may affect roughness of a copper wiring. Further, since TiN has crystallinity, the roughness of the metal wiring tends to be increased by a crystal grain boundary (crystal grain). Therefore, after the etching process is performed on the wiring pattern, when copper is embedded in the wiring pattern without cleaning a surface of a substrate, the roughness of the metal mask made of TiN may be transferred to the copper wiring. This may increase a resistance value of the copper wiring. Further, in order to suppress such an increase in the resistance value of the copper wiring, a chemical which selectively cleans the metal mask made of TiN without damaging an underlying dielectric film may be used, but the chemical is expensive, which causes an increase in cost.

In this regard, in an embodiment of the present disclosure, there is provided a substrate processing method of forming a wiring pattern on an underlying dielectric film by etching, using, as a mask material, an IGZO-based metal oxide film having a predetermined composition. Accordingly, it is possible to reduce roughness of a metal wiring. In addition, an example of forming a damascene structure is exemplified as a substrate processing method according to a first embodiment of the present disclosure, and an example of forming a dual damascene structure is exemplified as a substrate processing method according to a second embodiment of the present disclosure.

### First Embodiment

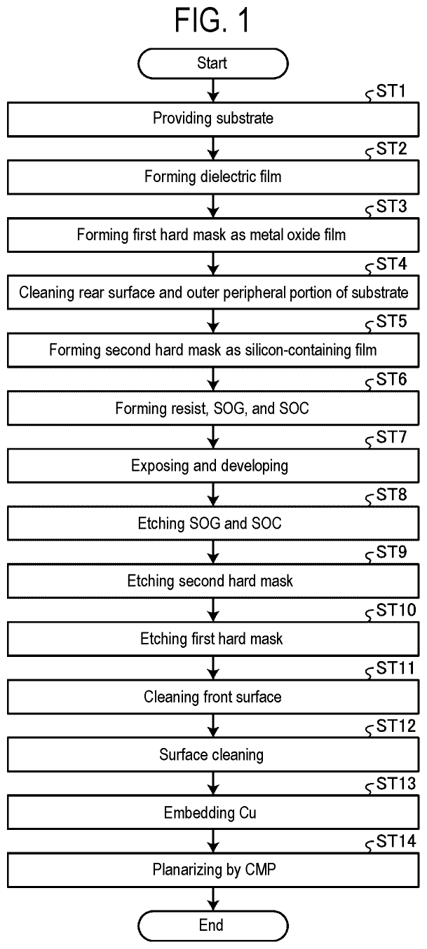

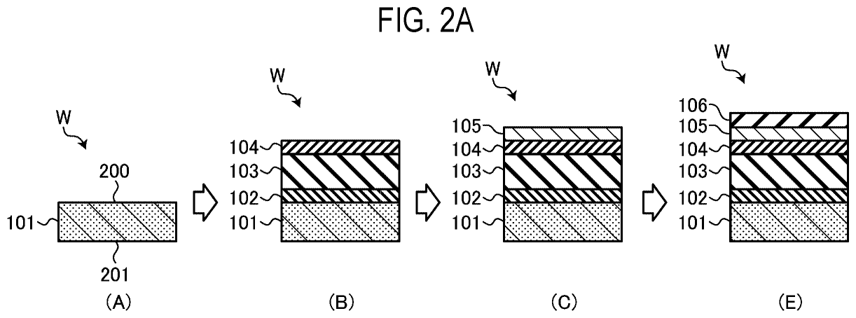

The substrate processing method according to the first embodiment of the present disclosure will be described with reference to FIGS. 1, 2A, 2B, and 2C. FIG. 1 is a flowchart illustrating an example of the substrate processing method according to the first embodiment. FIGS. 2A to 2C are schematic cross-sectional views illustrating operations of forming the damascene structure.

### <Operation ST1: Preparing Substrate>

In Operation ST1, a substrate on which a metal wiring is to be formed is provided. The substrate is cleaned to remove particles on a front surface thereof and then loaded into a processing container of a film forming apparatus which will be described later. In an example of Operation A of FIG. 2A, a substrate W including a silicon substrate 101 is provided inside the processing container. The substrate W has a first surface 200 and a second surface 201 which is a surface opposite the first surface 200. The first surface 200 is a front surface of the substrate W, and the second surface 201 is a rear surface of the substrate W. Operation ST1 is an example of Operation A.

### <Operation ST2: Forming Dielectric Film>

Subsequently, in Operation ST2, a dielectric film is formed on the first surface 200. The dielectric film may be a low-k film having a low dielectric constant. The dielectric film may be a SiCOH film or a SiO film. A SiCN film may be provided between the dielectric film and the silicon substrate 101. Further, a cap film may be formed on the dielectric film. The cap film may be a SiO film or a SiN film. In the substrate W exemplified in Operation B of FIG. 2A, a SiCN film 102, a dielectric film 103, and a cap film 104 are formed on the silicon substrate 101 in that order. The cap film 104 has both a function of improving adhesion between the dielectric film 103 and a first hard mask 105 on the cap film 104, and a function of protecting the dielectric film 103 so as not to damage the dielectric film 103 when forming the first hard mask 105. The SiCN film 102 has a function of improving adhesion between the silicon substrate 101 and the dielectric film 103. Further, the SiCN film 102 and the cap film 104 may be omitted. Operation ST2 is an example of Operation B.

### <Operation ST3: Forming First Hard Mask>

Subsequently, in Operation ST3, a metal oxide film including one or two or more metal elements with a predetermined composition is formed as the first hard mask 105 on the dielectric film 103. The metal oxide film includes one of three elements such as indium (In), gallium (Ga), and zinc (Zn), or a plurality of metal elements. The formed metal oxide film includes no crystalline film. For example, the formed metal oxide film may be a non-crystalline film, that is, an amorphous film. A method of forming the metal oxide film may be physical vapor deposition (PVD) or atomic layer deposition (ALD), and may be performed at room temperature. The metal oxide film has a film thickness of about 5 nm to about 10 nm. In an example of Operation C of FIG. 2A, the first hard mask 105 as the metal oxide film is formed on the dielectric film 103 via the cap film 104. Operation ST3 is an example of Operation C. Operation ST3 may be performed by the film forming apparatus which forms the dielectric film 103 in Operation ST2.

### (Composition of First Hard Mask)

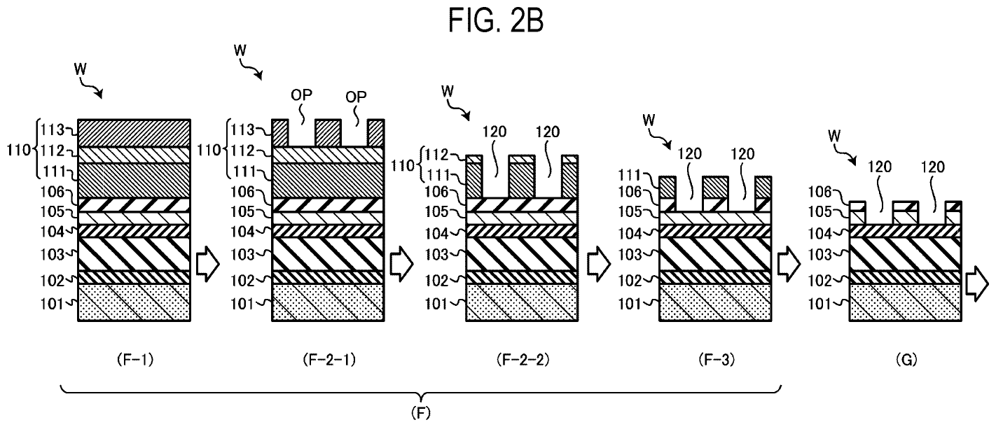

FIG. 3 is a view illustrating a composition ratio of the metal elements of the first hard mask. The composition ratio of the metal elements included in the metal oxide film as the first hard mask 105 satisfies conditions falling within a preset region Ar as shown in FIG. 3. For example, a composition ratio of one or two or more metal elements such as indium (In), gallium (Ga), and zinc (Zn), which are included in the metal oxide film, may fall within the region Ar as shown in FIG. 3. Specifically, white circles ◯ in FIG. 3 represent examples of the composition ratio of the metal elements included in the metal oxide film when the metal oxide film becomes an amorphous film. For example, white circles a1, a2, and a3 on a line having indium (In) and gallium (Ga) as vertices are examples of the composition ratios of the metal elements included in the metal oxide film when the metal oxide film becomes the amorphous film. In the composition ratios defined on the line having indium (In) and gallium (Ga) as the vertices, the composition ratio of indium with respect to gallium included in the metal oxide film is increased toward the vertex of indium. The composition ratio of gallium with respect to indium included in the metal oxide film is increased toward the vertex of gallium.

The metal oxide film indicated by the white circle a1 is an In₂O₃ film in which the composition ratio of indium, gallium, and zinc is 1:0:0. The metal oxide film indicated by the white circle a3 is a Ga₂O₃ film in which the composition ratio of indium, gallium, and zinc is 0:1:0. The metal oxide film indicated by the white circle a2 on the line is an InGaO₃ film in which the composition ratio of indium, gallium, and zinc is 1:1:0. The metal oxide film indicated by a white circle a4 as a central vertex is an IGZO film in which distances to vertices of indium, gallium, and zinc are the same, and the composition ratio of indium, gallium, and zinc is 1:1:1. The metal oxide films such as the In₂O₃ film, the InGaO₃ film, and the IGZO film having the respective composition ratios become amorphous films so that crystal grain boundaries are not clear. Therefore, when the dielectric film 103 is etched using the metal oxide film as the first hard mask 105, the roughness of the copper wiring embedded in the dielectric film 103 may be decreased.

Meanwhile, a black circle a5 in FIG. 3 represents an example of a composition ratio of the metal elements included in the metal oxide film when the metal oxide film becomes a crystalline film. The metal oxide film indicated by the black circle a5 is a “zinc oxide (ZnO) film” in which the composition ratio of indium, gallium, and zinc is 0:0:1. The ZnO film is a crystalline film, and a crystal grain boundary thereof is clear. Therefore, when the dielectric film 103 is etched using the metal oxide film as the first hard mask 105, roughness of a sidewall of a recess formed in the dielectric film 103 may be increased. As a result, the resistance value of the copper wiring embedded in the recess is increased. This makes it difficult to use the ZnO film as the first hard mask 105.

As described above, the metal oxide film is formed such that the composition ratios of one or two or more metal elements included in the metal oxide film satisfy the conditions falling within the region Ar shown in FIG. 3. Accordingly, the formed metal oxide film becomes a film including no crystalline film. For example, the formed metal oxide film is a film which is unlikely to be crystallized. The expression “the film which is unlikely to be crystallized” used herein is not limited to an amorphous film including no crystal, that is, an amorphous film which is not crystallized, but may be a non-crystalline film including fine crystals with very small grain boundaries at a portion of the film.

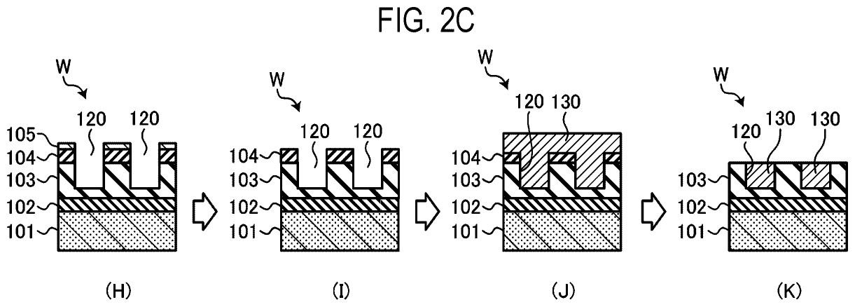

FIG. 4 is a graph illustrating an example of a crystallinity of the first hard mask 105. FIG. 4 shows results obtained by analyzing a sample of the first hard mask 105 formed in Operation ST3 using an X-ray diffractometer. The horizontal axis in FIG. 4 represents an angle 2θ formed by a surface of the sample of the first hard mask 105 and an incident X ray. The vertical axis in FIG. 4 represents an intensity of the X ray generated from the sample.

When the first hard mask 105 is the ZnO film, a peak representing a crystal grain boundary exists in the vicinity of 35 degrees, a half bandwidth of the peak is considered as a size of the crystal grain boundary, and the first hard mask 105 became a film crystallized in at least a portion thereof. When the first hard mask 105 is other films shown in the graph of FIG. 4 other than the ZnO film, the first hard mask 105 became an amorphous film which has no sharp vertex and is not crystallized, or an amorphous film including fine crystals. That is, the films shown in the graph of FIG. 4 other than the ZnO film are considered as films which are unlikely to be crystallized.

For example, the metal oxide film as an amorphous film (non-crystalline film) may be used as the first hard mask 105. Further, when the metal oxide film is a film such as an amorphous film, which includes at least one of indium, gallium or zinc with a predetermined composition and is unlikely to be crystallized, the metal oxide film may be used as the first hard mask 105. Further, for example, a metal oxide film, which contains at least one of indium or gallium, and zinc as metal elements, where a composition ratio of zinc to all the metal elements is 80% or less, is considered as a film such as an amorphous film which is unlikely to be crystallized. Therefore, the metal oxide film with such a composition ratio may be used as the first hard mask 105. Further, in the case of a ZnO film containing zinc alone as the metal element, a crystallized portion is restricted, and crystal grain boundaries are not clear as a whole so that the ZnO film may be considered as a film which is unlikely to be crystallized. Thus, the ZnO film may be used as the first hard mask 105.

### (Film Formation Conditions for First Hard Mask)

In Operation ST3, an example of film formation conditions for the first hard mask 105 by the PVD method is as follows.
Metal oxide film: IGZO
Composition ratio of metal oxide film: In:Ga:Zn:O=1:1:1:4
Film formation temperature (stage temperature): 25 degrees C. to 400 degrees C.
DC bias power (bias power value supplied to stage): 800 W to 1,400 W
Gas species: 02 gas and Ar gas
Flow rate ratio of O₂ gas to Ar gas: 1:9
Film thickness of metal oxide film: 5 nm
Film formation time: 32 secs
Film formation rate: 1.54 Å/sec

### <Operation ST4: Cleaning Substrate>

After forming the first hard mask 105, in Operation ST4, the second surface 201 which is the rear surface of the substrate W, and an outer peripheral portion of the first surface 200 which is an outer peripheral portion of the front surface of the substrate W, are cleaned. For example, in the cleaning, dilute hydrogen fluoride (DHF), hydrochloric acid-hydrogen peroxide mixture (HPM), or the like may be used. DHF is, for example, an aqueous solution of hydrogen fluoride (HF) diluted at a volume ratio of 1:100. HPM is a chemical liquid in which hydrochloric acid (HCl), oxygenated water (H₂O₂), and deionized water (DIW) are mixed. Accordingly, when forming the first hard mask 105 in Operation ST3, a metal adhering to the rear surface of the substrate and the outer peripheral portion (that is, a bevel portion) of the front surface of the substrate is removed, thereby avoiding metal contamination when forming a second hard mask in a next operation. Operation ST4 is an example of Operation D. Operation ST4 may be performed by a cleaning apparatus which will be described later.

### <Operation ST5: Forming Second Hard Mask>

After cleaning the substrate W, in Operation ST5, a silicon-containing film is formed as the second hard mask. The silicon-containing film may be a SiO film or a SiN film. The second hard mask has a film thickness of about 10 nm to about 30 nm. In an example of Operation E of FIG. 2A, a second hard mask 106 composed of a SiO film or a SiN film is formed on the first hard mask 105. Operation ST5 is an example of Operation E. Operation ST5 may be performed by the film forming apparatus which performs Operation ST2 or Operation ST3.

### <Operation ST6: Forming Resist-Related Film>

Subsequently, in Operation ST6, a resist-related film for pattern formation is formed on the second hard mask 106. The resist-related film for pattern formation formed herein is an example of a “resist-related first film having a predetermined pattern formed therein” for forming a recess corresponding to the predetermined pattern (hereinafter, referred to as a “first pattern”) in the first hard mask 105. In an example of Sub-operation F-1 of Operation F of FIG. 2B, a resist-related first film 110 is formed on the second hard mask 106. Hereinafter, the resist-related first film will be referred to as a “first film 110.” The first film 110 has a structure in which a spin-on-carbon (SOC) film 111, a spin-on-glass (SOG) film 112, and a resist film 113 are sequentially stacked on the second hard mask 106. In Operation ST6, a resist coating apparatus (not illustrated) coats the SOC film 111, the SOG film 112, and the resist film 113 on the substrate W, and subsequently, a thermal processing apparatus (not illustrated) may perform thermal processing on the substrate W. In Operation ST6, the film forming apparatus may form a carbon film instead of the SOC film 111 by the chemical vapor deposition (CVD) method. Further, the first film 110 is not limited to a triple-layer structure. The first film 110 may have a double-layer structure composed of the SOC film 111 and the resist film 113 made of a metal. The first film 110 may have a double-layer structure of the resist film 113, and the SOC film 111 or the SOG film 112. The first film 110 may have a single-layer structure composed of any one of the resist film 113, the SOC film 111, the SOG film 112, or the carbon film. Operation ST6 is an example of Sub-operation F-1 of Operation (F).

### <Operation ST7: Exposing and Developing Resist Film>

Subsequently, in Operation ST7, the resist film 113 is exposed to extreme ultraviolet (EUV) light having a wavelength of 13.5 nm, which is irradiated from an EUV light source. In Operation ST7, an exposure processing is performed on the resist film 113 by an exposing apparatus (not illustrated). A light source included in the exposure apparatus is not limited to the EUV light source, and may be a KrF light source or the like. After the resist film 113 is exposed, a development processing is performed on the resist film 113 by a developing apparatus (not illustrated). As a result, the first pattern is formed in the resist film 113. In an example of Sub-operation F-2-1 of Operation F of FIG. 2B, a first pattern OP having a pitch of 20 nm to 40 nm is formed on the resist film 113. After the development processing, the thermal processing may be performed on the substrate W. Operation ST7 is an example of Sub-operation F-2 of Operation F.

### <Operation ST8: Etching SOG and SOC>

Subsequently, in Operation ST8, the SOG film 112 and the SOC film 111 are etched so that the first pattern is transferred to the SOG film 112 and the SOC film 111. Dry etching for the SOG film 112 and the SOC film 111 may be performed by a same etching apparatus. Operation ST8 may be performed by an etching apparatus which will be described later. In the etching apparatus, two radio-frequency power sources which output radio-frequency powers of different wavelengths are connected to an upper electrode and a lower electrode. Source RF power of 100 MHz is supplied to the upper electrode and bias RF power of 13 MHz is supplied to the lower electrode. The SOG film 112 may be etched using, for example, plasma of a CF₄ gas and an Ar gas. The SOC film 111 may be etched using, for example, plasma of an O₂ gas, plasma of the O₂ gas and a COS gas, or plasma of a H₂ gas and a N₂ gas. In the etching in Operation ST8, the SOC film 111 may be etched until the second hard mask 106 is exposed. During the etching, the first hard mask 105 is protected by the second hard mask 106. As illustrated in Sub-operation F-2-2 of Operation F of FIG. 2B, the first pattern OP of the resist film 113 is transferred to the SOG film 112 and the SOC film 111, so that a recess 120 corresponding to the first pattern OP of the first film 110 is formed in the SOG film 112 and the SOC film 111. Operation ST8 is an example of Sub-operation F-2 included in Operation F. The recess 120 has, for example, a line-and-space shape.

### <Operation ST9: Etching Second Hard Mask>

Subsequently, in Operation ST9, the second hard mask 106 is etched. The etching for the second hard mask 106 may be performed by the etching apparatus which etches the SOG film 112 and the SOC film 111. The second hard mask 106 is etched by a mixture gas including a plurality of gas species among a CF₄ gas, a C₄F₈ gas, a C₄F₆ gas, a CHF₃ gas, a CH₂F₂ gas, an O₂ gas, and an Ar gas. As a result, as illustrated in Sub-operation F-3 of Operation F of FIG. 2B, the recess 120 corresponding to the first pattern OP is formed on the second hard mask 106. Operation ST9 is an example of Sub-operation F-3 included in Operation F.

### <Operation ST10: Etching First Hard Mask>

After etching the second hard mask 106, in Operation ST10, the first hard mask 105 is etched. Accordingly, as illustrated in Operation G of FIG. 2B, the recess 120 corresponding to the first pattern OP is formed on the first hard mask 105. The etching for the first hard mask 105 is performed until the cap film 104 is exposed. The etching for the first hard mask 105 may be performed by the etching apparatus which etches the second hard mask 106. The first hard mask 105 is etched by, for example, plasma of a CH₄ gas and a H₂ gas. The CH₄ gas generates deposits of CH. Thus, a composition ratio of the H₂ gas and the CH₄ gas is set to x:1 (x is 2 or more) such that an etching reaction exceeds a deposition reaction of CH. As a value of x increases, a larger amount of H₂ gas is added.

However, the gas species are not limited to the foregoing but may be a gas containing CH₃Cl and a gas containing C₂H₆. Further, the H₂ gas may be added. That is, the first hard mask 105 may be etched by a gas capable of generating CH₃ radicals. Operation ST9 and Operation ST10 are examples of Operation G.

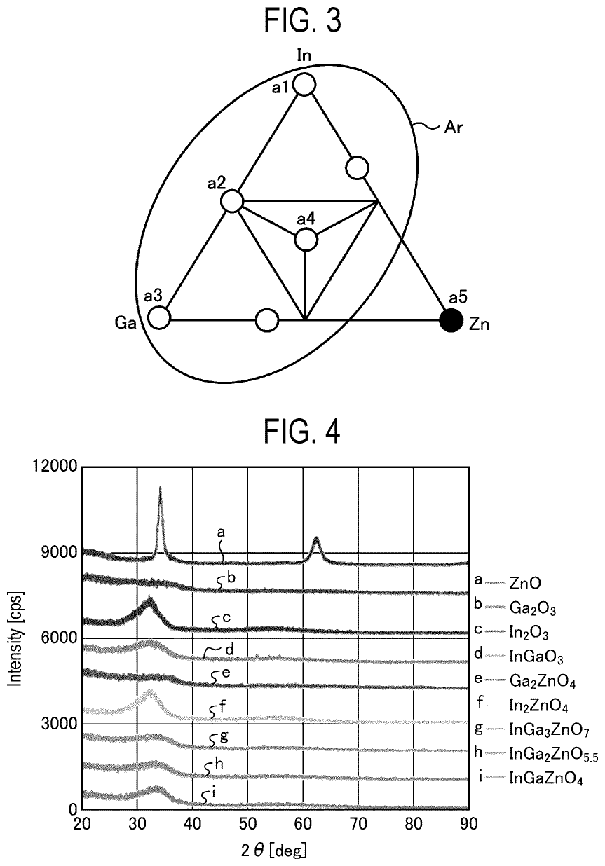

In Operation ST10, when an incomplete reaction product of methyl metal adheres to a sidewall of the second hard mask 106, it may affect an angle of a sidewall of the first hard mask 105. Therefore, in the etching of the first hard mask 105, a cyclic etching process using the plasma of the CH₄ gas and the H₂ gas and the plasma of the O₂ gas may be performed. FIG. 5 is a time chart illustrating an example of the etching process performed on the first hard mask. In Operation S1, the first hard mask 105 is etched to some extent by the plasm of the CH₄ gas and the H₂ gas. Thereafter, in Operation S2, the incomplete reaction product of the methyl metal, which adheres to the second hard mask 106 and the like, is ashed by the plasma of the O₂ gas, so that the angle of the sidewall of the first hard mask 105 is formed vertically. Operation S1 and Operation S2 are repeated a predetermined number of times. In the etching process for the first hard mask, the first hard mask 105 may be etched by the plasma of the CH₄ gas and the H₂ gas, and the O₂ gas may not be used.

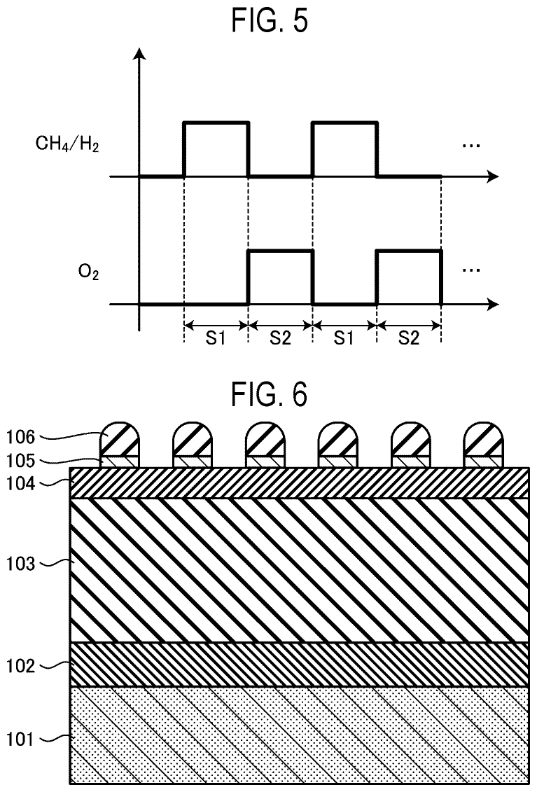

FIG. 6 is a view illustrating an example of results obtained by performing the cyclic etching process on the first hard mask 105. As the results obtained by performing the cyclic etching process as shown in FIG. 5, the sidewall of the first hard mask 105 was formed in a vertical shape.

### <Operation ST11: Etching Dielectric Film>

Subsequently, in Operation ST11, the dielectric film 103 is etched. When the cap film 104 is located on the dielectric film 103, the cap film 104 and the dielectric film 103 are etched. The etching of the dielectric film 103 is performed using a mixture gas including a plurality of gas species among a CF₄ gas, a C₄F₈ gas, a C₄F₆ gas, a CHF₃ gas, a CH₂F₂ gas, an O₂ gas, and an Ar gas. Accordingly, as illustrated in Operation H of FIG. 2C, the recess 120 corresponding to the first pattern OP is formed in the dielectric film 103. Operation ST11 is an example of Operation H.

### <Operation ST12: Cleaning Front Surface>

Subsequently, in Operation ST12, after etching the dielectric film 103, the front surface of the substrate W is wet-cleaned to remove the first hard mask 105 remaining on the front surface of the substrate W. In the cleaning at that time, DHF or a chemical liquid of citric acid may be used. Operation ST12 is an example of Operation I.

In addition, as an example of a cleaning condition, the cleaning the front surface may include an operation of cleaning the substrate with acid, an operation of cleaning the substrate with alkali, and an operation of rinsing the substrate with a rinsing liquid after such an acid-based cleaning and alkali-based cleaning. For example, in the operation of cleaning the substrate with acid, the substrate W is wet-cleaned by a chemical liquid of DHF or HPM for one minute. Thereafter, the substrate W is wet-cleaned by a chemical liquid of ammonia-hydrogen peroxide mixture cleaning (APM) for one minute. In the operation of cleaning the substrate with alkali, APM is a chemical liquid in which ammonium hydroxide (NH₄OH), oxygenated water (H₂O₂), and deionized water (DIW) are mixed with each other. Thereafter, the substrate W is rinsed with the rinsing liquid. As another example of the cleaning condition, the substrate W is wet-cleaned by the chemical liquid of the HPM for one minute, wet-cleaned by the chemical liquid of APM for one minute, and then rinsed with the rinsing liquid.

As an example of the chemical liquid used, DHF is, for example, an aqueous liquid of diluted hydrogen fluoride (HF) having a concentration of 0.5%, and is managed by a concentration meter. In terms of a concentration of DHF, DHF may be diluted in a range of 1:1,000 to 1:10,000. When DHF in such a concentration is used, the dielectric film 103 is not etched. As a result, as illustrated in Operation I of FIG. 2C, the first hard mask 105 is removed without damaging the dielectric film 103.

As an example of the chemical liquid used, HPM is, for example, a chemical liquid in which hydrochloric acid (HCl), oxygenated water (H₂O₂), and deionized water (DIW) are mixed with each other at a volume ratio of 1:2:40. APM is, for example, a chemical liquid in which the ammonium hydroxide, the oxygenated water, and the deionized water are mixed at a volume ratio of 1:2:40. The rinsing liquid is, for example, the deionized water (DIW).

After removing the first hard mask 105 by cleaning the front surface, in a flatness (roughness) of the recess 120 of the dielectric film 103, a line-width roughness (LWR) was 1.6 nm or less, and a line-edge roughness (LER) was 1.2 nm or less. The LER refers to an average value of line-edge roughness of left and right sidewalls of the recess (of the line-and-space shape). The LWR refers to line width roughness of the sidewalls of the recess, which is caused by the LER.

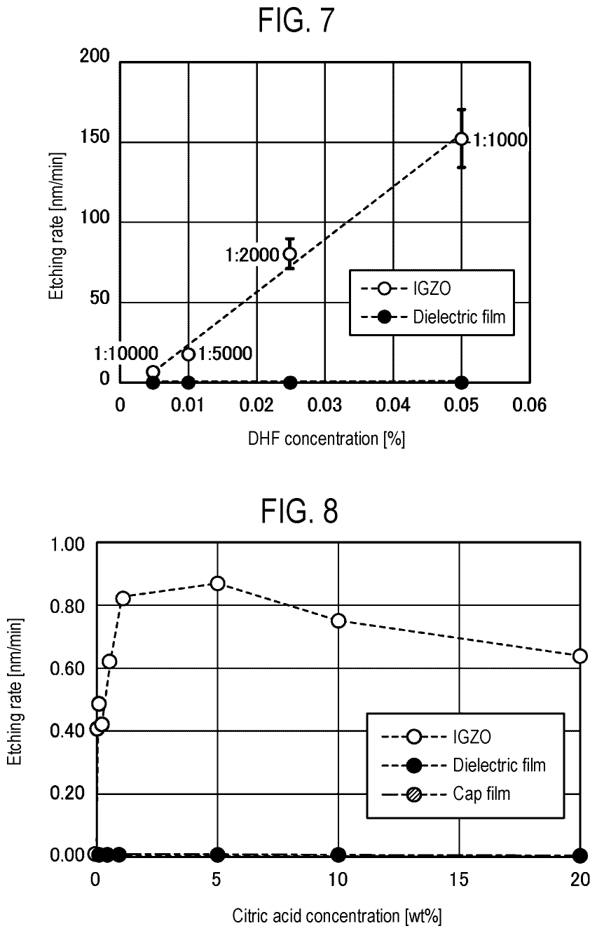

FIG. 7 is a graph illustrating an example of results obtained by performing the cleaning process on the front surface of the substrate. FIG. 7 shows dependence of etching rates on a concentration of DHF in an IGZO film and the dielectric film 103 when the first hard mask 105 is the IGZO film in which a composition ratio of In, Ga, Zn, and O is 1:1:1:4. In the graph of FIG. 7, the horizontal axis represents the concentration of DHF, and the vertical axis represents the etching rate of each of the IGZO film and the dielectric film 103. From a comparison between the IGZO film and the dielectric film 103 in terms of the etching rates, it was found that in the range of the concentration of DHF as shown in FIG. 7, the dielectric film 103 is not etched, and the first hard mask 105 as the IGZO film is removed. That is, it was found that the first hard mask 105 is removed without damaging the dielectric film 103.

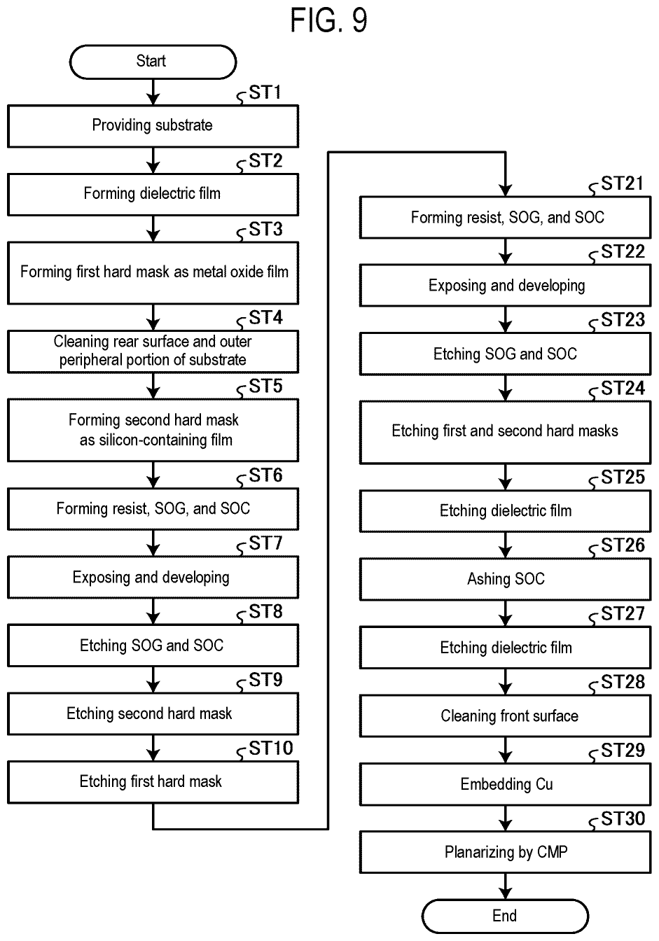

FIG. 8 is a graph illustrating another example of results obtained by performing the cleaning process on the front surface of the substrate. FIG. 8 shows dependence of etching rates on a concentration of citric acid in the IGZO film, the dielectric film 103, and the cap film 104 when the first hard mask 105 is the IGZO film in which the composition ratio of In, Ga, Zn, and O is 1:1:1:4. In the graph of FIG. 8, the horizontal axis represents the concentration of the citric acid, and the vertical axis represents the etching rate of each of the IGZO film, the dielectric film 103, and the cap film 104. From a comparison in the etching rates of the IGZO film, the dielectric film 103, and the cap film 104, it was found that in a range of the concentration of the citric acid as shown in FIG. 8, the dielectric film 103 and the cap film 104 were not etched, and the first hard mask 105 as the IGZO film was removed. That is, it was found that the first hard mask 105 is removed without damaging the dielectric film 103 and the cap film 104.

### <Operation ST13: Embedding Copper>

Subsequently, in Operation ST13, copper as an example of the metal is embedded in the recess 120 formed in the dielectric film 103. By a plating-based film formation, the copper is embedded in a space of the recess 120, and is also formed on the cap film 104. As a result, as illustrated in Operation J of FIG. 2C, a copper wiring layer 130 is formed in the recess 120 and on the cap film 104. The copper wiring layer 130 is an example of the metal embedded in the recess 120. If necessary, after a barrier layer is formed between the copper wiring layer 130 and the dielectric film 103 by the PVD method or the CVD method and a Cu seed is formed by the PVD method, the copper may be embedded in the recess 120 by the plating-based film formation. Operation ST13 is an example of Operation J.

### <Operation ST14: Planarizing>

Subsequently, in Operation ST14, the copper wiring layer 130 and the cap film 104, which are positioned at the upper portion, are cut by chemical mechanical polishing (CMP). As a result, as illustrated in Operation K of FIG. 2C, the formation of the copper wiring layer 130 as one layer in the damascene structure is completed. Operation ST14 is an example of Operation K.

The substrate processing method according to the first embodiment of the present disclosure proposes forming the copper wiring layer 130 having a low resistance by reducing the roughness of the wiring when forming the damascene structure. In this regard, the substrate processing method according to the second embodiment of the present disclosure proposes forming the copper wiring layer 130 having a low resistance by reducing the roughness of the wiring when forming a dual damascene structure.

### Second Embodiment

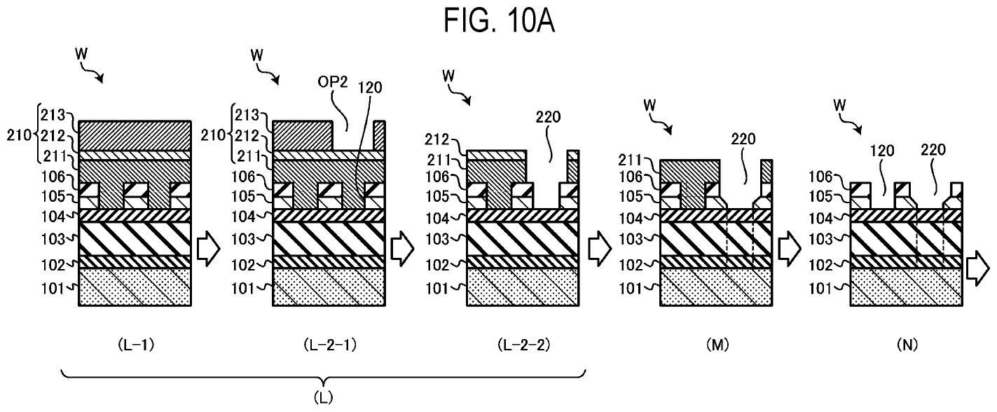

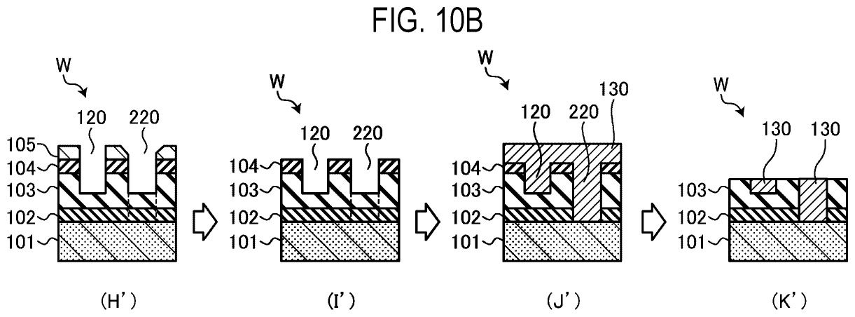

The substrate processing method according to the second embodiment of the present disclosure will be described with reference to FIGS. 9, 10A, and 10B. FIG. 9 is a flowchart illustrating an example of the substrate processing method according to the second embodiment. FIGS. 10A and 10B are schematic cross-sectional views illustrating operations of forming the dual damascene structure. Further, in the substrate processing method according to the second embodiment, the same operations as those of the substrate processing method according to the first embodiment shown in FIG. 1 will be designed by the same reference numerals.

### <Operations ST1 to ST10: Preparing Substrate to Etching First Hard Mask>

Operation ST1 of preparing the substrate to Operation ST10 of etching the first hard mask 105 are identical to Operations ST1 to ST10 of the substrate processing method according to the first embodiment, and therefore descriptions thereof will be omitted. As described above, Operation A of FIG. 2A to Operation G of FIG. 2B are performed so that the recess 120 is formed in the first hard mask 105.

### <Operation ST21: Forming Resist-Related Film>

In the case of the dual damascene structure, after the recess 120 is formed in the first hard mask 105, a resist-related film for via pattern formation is formed again.

In Operation ST21, the resist-related film for via pattern formation is formed on the second hard mask 106. The resist-related film for via pattern formation formed herein is an example of a “resist-related second film having a second pattern formed therein” for forming a via corresponding to a predetermined pattern (hereinafter, referred to as the “second pattern”) in the first hard mask 105 and the second hard mask 106. In an example of Sub-operation F-1 of Operation F of FIG. 2B, a resist-related first film 110 is formed on the second hard mask 106. Hereinafter, the resist-related first film will be referred to as a “first film 110.” In an example of Operation L-1 of Operation L of FIG. 10A, a resist-related second film 210 is formed on the second hard mask 106. Hereinafter, the resist-related second film 210 is referred to as a “second film 210.” The second film 210 has a structure in which a SOC film 211, a SOG film 212, and a resist film 213 are sequentially stacked on the second hard mask 106. A method of forming the second film 210 and a layer structure of the second film 210 in Operation ST21 may be the same as the method of forming the first film 110 and the layer structure of the first film 110, which are described in Operation ST6. Operation ST21 is an example of Operation L-1 included in Operation L.

When the first hard mask 105 is formed of TiN as a mask material, a halogen-based gas is used to form a recess in TiN as the mask material. Therefore, a halogen element remains on a sidewall of TiN. The halogen element may damage the SOC film 211 when the SCO film 211 is formed. As a result, voids may be generated in the SOC film 211.

On the other hand, in this substrate processing method, IGZO is used as the mask material for the first hard mask 105. In this case, experiment was conducted to confirm a state of voids in the SOC film 211. In the experiment, in a case where the wet cleaning is not performed just before Operation ST21, a case where the water cleaning is performed just before Operation ST21, or a case where the APM-based wet cleaning is performed just before Operation ST21, the presence or absence of voids in twenty sites of the SOC film 211 was checked. As a result, in any case, no void was generated in the SOC film 211. Further, a tape test in which a tape is attached to a front surface of the SOC film 211 at three places, that is, a center, a middle, and an edge of the substrate W, was conducted. It has been confirmed that for either the water cleaning or the APM-based wet cleaning except for the wet cleaning, the SOC film 211 having excellent adhesion was formed.

### <Operation ST22: Exposing and Developing Resist-related Film>

Subsequently, in Operation ST22, after aligning the recess 120 and a via 220, a mask is positioned such that the second pattern is formed on the recess 120 of a line-and-space shape, and an exposure process is performed on the resist film 213. An exposure method and a development method in Operation ST22 may be similar to the exposure method and the development method in Operation ST7. As a result, as illustrated in Operation L-2-1 of Operation L of FIG. 10A, a second pattern OP2 is formed in the resist film 213 above the recess 120. Operation ST22 is an example of Operation L-2 included in Operation L.

### <Operation ST23: Etching SOG and SOC>

Subsequently, in Operation ST23, the SOG film 212 and the SOC film 211 are etched to form the via 220 corresponding to the second pattern OP2 in the SOG film 212 and the SOC film 211. A method of etching the SOG film 212 and the SOC film 211 may be similar to the etching method in Operation ST8. As a result, as illustrated in Operation L-2-2 of Operation L of FIG. 10A, the via 220 is formed in the SOG film 212 and the SOC film 211. Operation ST23 is an example of Operation L-2 included in Operation L.

### <Operation ST24: Etching First Hard Mask and Second Hard Mask>

In Operation ST24, the first hard mask 105 and the second hard mask 106 are etched. A method of etching the first hard mask 105 and the second hard mask 106 may be similar to the etching method in Operations ST9 and ST10. As a result, as illustrated in Operation M of FIG. 10A, the via 220 is formed in the first hard mask 105 and the second hard mask 106.

### <Operation ST25: Etching Dielectric Film>

Subsequently, in Operation ST25, the dielectric film 103 is etched. The etching in Operation ST25 is performed using a mixture gas including a plurality of gas species among a CF₄ gas, a C₄F₈ gas, a C₄F₆ gas, a CHF₃ gas, a CH₂F₂ gas, an O₂ gas, and an Ar gas. Further, a via formed in the dielectric film 103 has a small critical dimension (CD) and a high aspect ratio. Thus, as an etching condition in Operation ST25, high bias power is applied to a stage. Since the via 220 fully penetrates through the dielectric film 103 when etching the recess 120 in a subsequent operation, the etching of the via 220 in Operation ST25 may be performed to a middle of the dielectric film 103. As a result, as illustrated in Operation M of FIG. 10A, the via 220 corresponding to the second pattern OP2 is formed in the dielectric film 103. Operation ST25 is an example of Operation M.

### <Operation ST26: Etching SOC Film>

Subsequently, in Operation ST26, the SOC film 211 is ashed. The ashing of the SOC film 211 is performed with plasma of a H₂ gas and a N₂ gas or plasma of a CO₂ gas instead of the plasma of the O₂ gas so as not to damage the underlying dielectric film 103. As a result, as illustrated in Operation N of FIG. 10A, the SOC film 211 is ashed. Operation ST26 is an example of Operation N.

### <Operation ST27: Etching Dielectric Film>

By ashing the SOC film 211, the recess 120 is exposed from the front surface. Subsequently, in Operation ST27, the dielectric film 103 is etched according to the recess 120 and the via 220. An etching method at that time may be similar to the etching method in Operation ST11. Through Operation ST27, the via 220 fully penetrates through the dielectric film 103 so that the silicon substrate 101 is exposed. As a result, as illustrated in Operation H′ of FIG. 10B, the via 220 and the recess 120 are formed. For example, pitches of the via 220 and the recess 120 may be micro-fabricated at a level of about 30 nm. Operation ST27 is an example of Operation H′ of forming the via 220 penetrating through the dielectric film 103 and the recess 120 in the dielectric film 103 after Operation N.

### <Operation ST28: Cleaning Front Surface>

Subsequently, in Operation ST28, after etching the dielectric film 103, as illustrated in Operation I′ of FIG. 10B, the front surface of the substrate W is wet-cleaned to remove the first hard mask 105 remaining on the front surface of the substrate W. A cleaning method at the time may be similar to the cleaning method in Operation ST12. Operation ST28 is an example of Operation I.

### <Operation ST29: Embedding Copper>

Subsequently, in Operation ST29, copper as an example of a metal is embedded in the recess 120 and the via 220 which are formed in the dielectric film 103. As a result, as illustrated in Operation J′ of FIG. 10B, a copper wiring layer 130 is formed in the recess 120, in the via 220, and on the cap film 104. If necessary, a barrier layer may be formed between the copper wiring layer 130 and the dielectric film 103 by the CVD method. Operation ST29 is an example of Operation J of embedding the metal in the recess 120 and the via 220 which are formed in the dielectric film 103.

### <Operation ST30: Planarizing>

Subsequently, in Operation ST30, the copper wiring layer 130 and the cap film 104 positioned at an upper portion are cut by the CMP method. As a result, as illustrated in Operation K′ of FIG. 10B, the formation of the copper wiring layer 130 as one layer in the dual damascene structure is completed. Operation ST30 is an example of Operation K.

### Effects

According to the substrate processing method according to the first embodiment of the present disclosure and the substrate processing method according to the second embodiment of the present disclosure, the dielectric film 103 is etched using, as a mask material of the first hard mask 105, the IGZO-based metal oxide film having the predetermined composition ratio within the region Ar shown in FIG. 3. As a result, the recess 120 is formed in the dielectric film 103. The metal oxide film having the predetermined composition ratio within the region Ar of FIG. 3 is an amorphous film and crystal grain boundaries thereof are not clear. For this reason, when the dielectric film 103 is etched using the metal oxide film as the first hard mask 105, LER and LWR values of the recess 120 transferred to the dielectric film 103 become small. Accordingly, it is possible to reduce the resistance of the copper wiring layer 130 embedded in the recess 120.

For example, according to the substrate processing methods of the first embodiment and the second embodiment, the material of the first hard mask 105 is changed from TiN to an amorphous metal oxide film. The metal oxide film is an oxide including one or two or more elements among indium, gallium, and zinc. The metal oxide film including indium, gallium, zinc or the like has a low vapor pressure. Thus, during the etching of the dielectric film 103, consumption of the first hard mask 105 is small, and resistant to etching is high. By using such advantages, although the TiN mask having a film thickness of about 20 nm was formed in the related art, in the substrate processing methods of the present disclosure, the amorphous metal oxide film having a film thickness of about 5 nm is formed as the first hard mask 105. This makes it possible to reduce the aspect ratio of the first hard mask 105. Thus, a surface tension of the first hard mask 105 is lowered, which makes it difficult for the wiggling of the wiring to occur, thereby reducing the roughness of the recess 120 formed in the dielectric film 103.

In practice, in a wiring pattern having a pitch of 40 nm, the dielectric film 103 was etched using the metal oxide film having a film thickness of 5 nm as the first hard mask 105. Accordingly, the selectivity of the first hard mask 105 with respect to the dielectric film 103 was increased by about 32 times. As compared with the TiN mask having a film thickness of about 20 nm in the related art, the aspect ratio was reduced to a level of about ¼, which allowed reduction in the occurrence of the wiggling of the wiring.

In addition, the TiN mask is a crystalline film. In this regard, in the substrate processing methods according to the first embodiment and the second embodiment, by adjusting the composition ratio of the metal elements of the IGZO-based metal oxide film, it is possible to form the first hard mask 105 as an amorphous film. A region of the composition ratio at which the first hard mask 105 becomes the amorphous film is the region Ar of FIG. 3. When a metal oxide having high crystallinity is used for the first hard mask 105, the roughness of the recess 120 and the via 220 formed in the dielectric film 103 is deteriorated. Therefore, in order to form, as the first hard mask 105, a metal oxide film having a composition, which is unlikely to be crystallized, the composition ratio of the metal elements included in the metal oxide film is adjusted. Accordingly, it is possible to improve the roughness of the recess 120 and the via 220, which are formed in the dielectric film 103.

In addition, the IGZO-based metal oxide film has high transparency. Thus, the IGZO film having a film thickness of 5 nm has transparency of 95% or more. On the other hand, the transmittance of the TiN mask having a film thickness of 20 nm is about 60%. Thus, in the substrate processing methods according to the first embodiment and the second embodiment, in a multilayer wiring using the IGZO-based metal oxide film as the first hard mask 105, the via 220 and the recess 120 are likely to be aligned.

In addition, in the etching of the first hard mask 105, a halogen gas such as a Cl₂ gas was used to etch the TiN mask in the related art. On the other hand, for the first hard mask 105, the CH₄ gas and the H₂ gas are used. When etching the TiN mask with the Cl₂ gas, the recess 120 and the via 220 are unlikely to be machined vertically and thus, the TiN mask may have a tapered shape. Meanwhile, when etching the metal oxide film with the CH₄ gas and the H₂ gas, as illustrated in FIG. 6, the recess 120 and the via 220 have a vertical shape. Since the shape of the first hard mask 105 affects the roughness, by allowing the first hard mask 105 to have the vertical shape, the roughness of the recess 120 and the like formed in the dielectric film 103 may be reduced.

Further, in the etching based on the halogen gas, halogen atoms are likely to remain on the patterned surface of the recess 120 and the like. As a result, when performing a second round of coating on the SOC film 211 having the dual damascene structure, voids are likely to occur in the SOC film 211. On the other hand, when the IGZO-based metal oxide film is used as the first hard mask 105, the SOC film 211 may be formed with excellent adhesion and without a void, even without performing the cleaning before forming a second round of the SOC film 211.

In addition, in the case of the TiN mask, after etching the dielectric film 103, the barrier film and the copper are embedded without the cleaning. As a result, the roughness of the TiN mask is likely to be transferred to the copper wiring as it is. On the other hand, in the substrate processing methods of the present disclosure, the IGZO-based metal oxide film is used as the first hard mask 105. In this case, since the first hard mask 105 is completely removed using DHF or citric acid after etching the dielectric film 103, the roughness of the metal oxide film as the first hard mask 105 is hardly transferred to the copper wiring. As described above, by providing the material of the metal oxide film and the substrate processing method suitable for the material, it is possible to reduce the roughness of the wiring according to a wiring forming method in the related art.

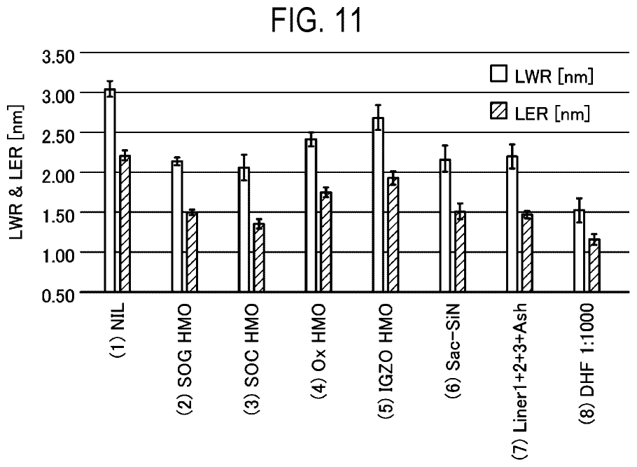

Results obtained by measuring the roughness of the wiring according to the substrate processing method of the present disclosure will be described with reference to FIG. 11. FIG. 11 is a view illustrating an example of roughness in operations of the substrate processing method. FIG. 11 shows that the operations of the substrate processing method affect the roughness of the wiring from values of LER representing the roughness of the line edge and LWR representing the roughness of the line width.

In “(1) NIL” of FIG. 11, LER of the first pattern OP formed in the resist film 113 after the exposure and development was about 2.2 nm and LWR thereof was about 3.0 nm. In “(2) SOG HMO,” LER of the recess 120 formed in the SOG film 112 was about 1.5 nm and LWR thereof was about 2.2 nm. In “(3) SOC HMO,” LER of the recess 120 formed in the SOC film 111 was about 1.3 nm and LWR thereof was about 2.1 nm.

In “(4) Ox HMO,” LER of the recess 120 formed in the second hard mask 106 as the SiO film was about 1.8 nm and LWR thereof was about 2.4 nm. In “(5) IGZO HMO,” LER of the recess 120 formed in the first hard mask 105 as the IGZO film was about 1.9 nm and LWR thereof was about 2.7 nm. In “(6) Sac-SiN,” LER of the recess 120 formed in the cap film 104 as the SiN film was about 1.5 nm and LWR thereof was about 2.2 nm.

In “(7) Liner to Liner1+2+3+4+Ash,” LER of the recess 120 formed in the dielectric film 103 before the cleaning after etching the dielectric film 103 was about 1.5 nm and LWR thereof was about 2.2 nm. In “(8) DHF 1:1,000,” after etching the dielectric film 103, the front surface of the substrate was cleaned by the chemical liquid made of DHF, which is, for example, an aqueous solution of hydrogen fluoride (HF) diluted at a volume ratio of 1:1,000. Accordingly, LER of the recess 120 formed in the dielectric film 103 was improved to about 1.1 nm and LWR thereof was improved to about 1.5 nm. That is, in comparison to the roughness of the first pattern OP of the resist film 113 after exposure and development, the roughness of the recess 120 of the dielectric film 103 was approximately improved in half by cleaning the front surface after etching the dielectric film 103.

A first reason that the roughness is improved according to the substrate processing method of the present disclosure is that the selectivity of the first hard mask 105 is high and the aspect ratio of the first hard mask 105 is smaller than that of the TiN mask in the related art. Thus, the roughness of the first hard mask 105 becomes smaller due to wiggling. For this reason, it is considered that the roughness of the recess 120 of the dielectric film 103 was decreased. A second reason is that the first hard mask 105 is the metal oxide film which is exclusive of a crystalline film such as an amorphous film and thus, the effect of transferring the roughness to the dielectric film 103 due to the crystal grain boundaries is low. Therefore, it is considered that the roughness of the recess 120 of the dielectric film 103 was decreased. A third reason is that residues of the first hard mask 105 is simply cleaned and removed by etching and cleaning the dielectric film 103. Therefore, it is considered that the roughness of the recess 120 of the dielectric film 103 was significantly improved.

### [Configuration Example of Film Forming Apparatus]

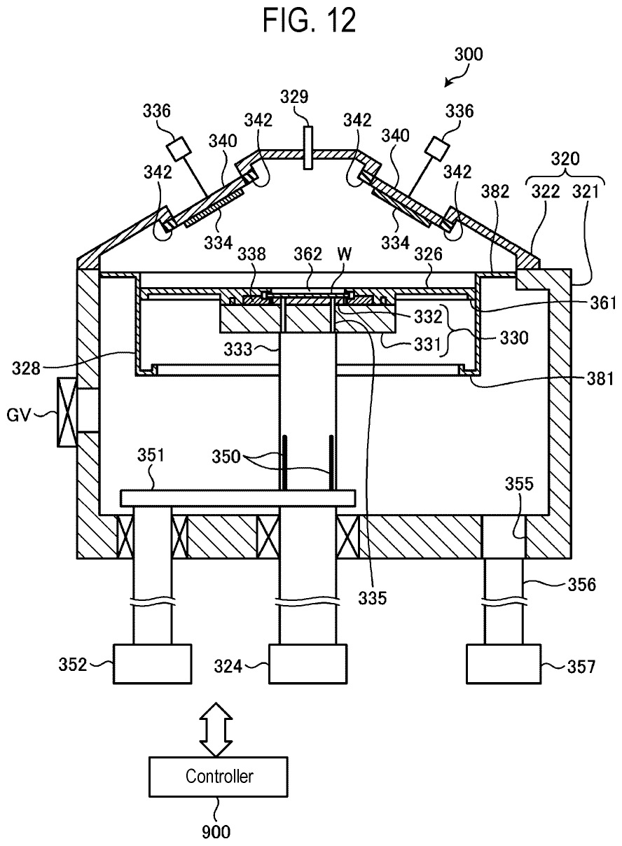

A configuration example of a film forming apparatus will be described with reference to FIG. 12. FIG. 12 is a view schematically illustrating a configuration of the film forming apparatus according to an embodiment. A film forming apparatus 300 forms the metal oxide film as the first hard mask 105 on the dielectric film 103 in, for example, Operation C. The film forming apparatus 300 may be used to perform other film forming operations. For example, the film forming apparatus 300 may be used to perform Operation B of forming the dielectric film, Operation E of forming the silicon-containing film as the second hard mask 106, and other film forming operations.

The film forming apparatus 300 is configured as a sputtering apparatus which forms the metal oxide film on the front surface of the substrate W by sputtering. The film forming apparatus 300 is an example of a configuration of the substrate processing apparatus.

The film forming apparatus 300 includes a processing container 320, a stage 330, and a target 334. The stage 330 is provided inside the processing container 320 controlled to be kept in a vacuum atmosphere. The substrate W on which a film is to be formed is placed on the stage 330. The target 334 has a surface exposed to an interior of the processing container 320 and releases a metal such as indium, gallium or zinc toward the substrate W on the stage 330. The processing container 320 includes a main body 321 which is a substantially cylindrical container having an opening at an upper portion, and a cover body 322 which closes the opening of the main body 321. An opening through which the substrate W is loaded and unloaded is formed in a sidewall of the main body 321. This opening is opened/closed by a gate valve GV.

The stage 330 includes a base 331 and an electrostatic chuck 332 for electrostatically attracting the substrate W on the stage 330. The electrostatic chuck 332 is disposed on an upper surface of the base 331. The base 331 has a substantially disk shape, and has a diameter larger than that of the substrate W. The base 331 includes a temperature adjustment module (not illustrated) configured to adjust a temperature of at least one of the stage 330 or the substrate W to a film formation temperature indicated in film forming conditions. The electrostatic chuck 332 includes an electrode (not illustrated) disposed inside a substantially disk-shaped ceramic having a diameter smaller than that of the substrate W. When a voltage is applied from a direct current power source (not illustrated) to the electrode inside the electrostatic chuck 332, the substrate W may be attracted to and held by an upper surface of the electrostatic chuck 332. Through-holes 335 through which lift pins 350 pass are formed in the base 331 and the electrostatic chuck 332. Bias power for ion attraction, which is indicated in the film forming conditions, is supplied from a radio-frequency power source (not illustrated) to the stage 330.

An annular shield ring 338 for preventing the metal released from the target 334 from being attached to a front surface of the base 331 is disposed on the upper surface of the stage 330. In order to prevent the base 331 from being exposed toward an opening 362 of a cover member 326, the shield ring 338 is disposed on the base 331 to surround a periphery of the electrostatic chuck 332.

A rotary shaft 333 for rotating the stage 330 around a central axis of the stage 330 is connected to a central portion of a lower surface of the base 331 of the stage 330. The rotary shaft 333 is provided to extend vertically downward from a connection portion with the base 331. The rotary shaft 333 penetrates through a bottom wall of the main body 321 of the processing container 320 and is connected to a driver 324. At a position at which the rotary shaft 333 penetrates through the main body 321, a seal member for air-tightly keeping an internal space of the processing container 320 is provided.

The driver 324 rotates the rotary shaft 333 around the central axis of the stage 330 to rotate the substrate W attractively held by the electrostatic chuck 332 of the stage 330. Further, the driver 324 may raise and lower the rotary shaft 333 to move the stage 330 between a delivery position at which the substrate W is transferred between an end effector of a transfer device and the stage 330, and a film formation position at which a film forming processing is performed on the substrate W.

In addition, the cover member 326 for forming a non-film-formation region (a region in which the metal oxide film is not formed) at an edge portion of the substrate W is disposed inside the processing container 320. The cover member 326 is constituted with a substantially circular ring-shaped member having a substantially circular opening 362 having a diameter smaller than that of the substrate W so as to correspond to a region in which the metal oxide film is formed. The cover member 326 is provided above an edge portion of the stage 330. An outer peripheral portion 361 of the cover member 326 protrudes downward.

A mask support 328 which separates the cover member 326 from the stage 330 when the stage 330 is lowered to the delivery position and supports the cover member 326 thus separated is provided inside the processing container 320. The mask support 328 is constituted with a substantially cylindrical member disposed to surround an outer peripheral surface of the cover member 326. A flange 382 is provided at an upper portion of the mask support 328 to be expanded toward an outer periphery thereof. The flange 382 is fixed to an inner wall of the main body 321.

The mask support 328 has a substantially cylindrical internal space which extends vertically so as not to interfere with a movement path of the cover member 326, which is defined by the vertical movement of the stage 330. Further, a support 381 is formed at a lower end portion of the mask support 328 along a circumferential direction of the mask support 328. The support 381 protrudes inward of the substantially cylindrical internal space and has a longitudinal cross-section formed in a hook shape. The support 381 is provided above the delivery position. Therefore, when the stage 330 is lowered to the delivery position, the outer peripheral portion 361 of the cover member 326 is locked to the support 381 of the mask support 328, so that the cover member 326 is separated from the stage 330.

A support 351 which supports a plurality of lift pins 350 is provided below the stage 330. A driver 352 raises and lowers the support 351.

An exhaust port 355 is formed in the bottom wall of the main body 321. An exhaust device 357 is connected to the exhaust port 355 via an exhaust pipe 356. The exhaust device 357 includes a pressure adjustment valve and a vacuum pump. By the pressure adjustment valve, an internal pressure of the processing container 320 is adjusted. The vacuum pump includes a turbo molecular pump, a dry pump, or a combination thereof.

A gas supply pipe 329 having a gas supply port for supplying a gas (e.g., an argon gas), which is a raw material of ions used for sputtering, to the internal space of the processing container 320 is provided at a substantially central portion of the cover body 322.

The cover body 322 is provided with a holder 340 which holds the target 334 and a holder support 342 for fixing the holder 340 to the cover body 322. The holder support 342 is made of an insulator and fixes the holder 340 to the cover body 322 while electrically insulating the holder 340 made of a metal from the cover body 322 made of, for example, a metal.

The holder 340 is connected to a power source 336. The power source 336 supplies direct current or alternating current power to the holder 340 to generate an electric field in the vicinity of the target 334 held by the holder 340. By the electric field generated in the vicinity of the target 334, ions are generated by dissociating a gas such as the O₂ gas or the Ar gas, which is supplied from the gas supply pipe 329, according to the film forming conditions for the first hard mask 105. The generated ions collide with the target 334 so that metal particles of at least one of indium (In), gallium (Ga), or zinc (Zn), which become raw materials of the metal oxide film, are released from the target 334. The metal particles released from the target 334 are deposited on the substrate W via the opening 362 of the cover member 326, so that the first hard mask 105 as the metal oxide film including one or two or more metal elements with a predetermined composition is formed on the front surface of the substrate W.

A controller 900 processes computer-executable commands which cause the film forming apparatus 300 to execute various processes described in the present disclosure. The controller 900 may be configured to control individual constituent elements of the film forming apparatus 300 to execute the various processes described herein. In an embodiment, a portion or the entirety of the controller 900 may be included in the film forming apparatus 300. The controller 900 may include a processor, a storage, and a communication interface. The controller 900 is implemented by, for example, a computer. The processor may be configured to perform various control operations by reading a program from the storage and executing the read program. This program may be stored in the storage in advance, or may be acquired via a medium if necessary. The acquired program is stored in the storage, and read from the storage and executed by the processor. The medium may be various non-transitory computer-readable storage media, or may be a communication line connected to the communication interface. The processor may be a central processing unit (CPU). The storage may include a random access memory (RAM), a read only memory (ROM), a hard disk drive (HDD), a solid state drive (SSD), or a combination thereof. The communication interface may communicate with the substrate processing apparatus via a communication line such as a local area network (LAN).

### [Configuration Example of Film Forming Apparatus]

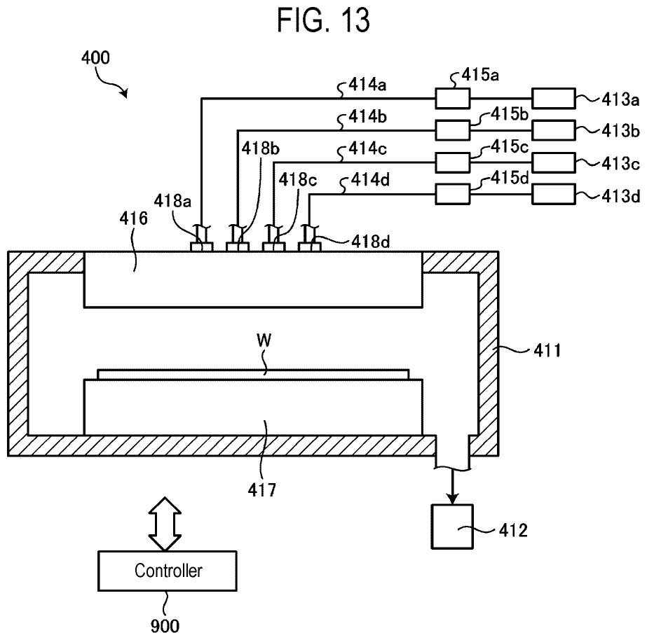

A configuration of another film forming apparatus will be described with reference to FIG. 13. FIG. 13 is a view schematically illustrating a configuration of a film forming apparatus according to an embodiment. Like the film forming apparatus 300, a film forming apparatus 400 is used when forming the metal oxide film on the dielectric film 103 in, for example, Operation C. Further, the film forming apparatus 400 may be used in other film forming operations.

The film forming apparatus 400 is configured as, for example, an atomic layer deposition (ALD) apparatus which forms the metal oxide film on the front surface of the substrate W by the ALD method. The film forming apparatus 400 is an example of the configuration of the substrate processing apparatus.

The film forming apparatus 400 includes a processing container 411, an exhaust device 412, a shower head 416, and a stage 417. The exhaust device 412 includes a vacuum pump which exhausts gas inside the processing container 411 and a pressure adjustment valve which adjusts an internal pressure of the processing container 411. The processing container 411 is controlled to be kept in a vacuum atmosphere of a preset pressure by the exhaust device 412.

Plural kinds of gases are supplied to the processing container 411 via the shower head 416. In this embodiment, the plural kinds of gases may be, for example, four gases including indium (In), gallium (Ga), zinc (Zn), and oxygen (O₂). An indium source 413a is connected to the shower head 416 via a pipe 414a. Further, a gallium source 413b is connected to the shower head 416 via a pipe 414b. Further, a zinc source 413c is connected to the shower head 416 via a pipe 414c. Further, an oxygen source 413d is connected to the shower head 416 via a pipe 414d.

A flow rate of a raw material gas of indium supplied from the indium source 413a is controlled by a flow rate controller 415a provided in the pipe 414a. The raw material gas of indium, the flow rate of which is controlled, is introduced from a gas supply port 418a to the shower head 416 via the pipe 414a. Further, a flow rate of a raw material gas of gallium supplied from the gallium source 413b is controlled by a flow rate controller 415b provided in the pipe 414b. The raw material gas of gallium, the flow rate of which is controlled, is introduced from a gas supply port 418b to the shower head 416 via the pipe 414b. Further, a flow rate of a raw material gas of zinc supplied from the zinc source 413c is controlled by a flow rate controller 415c provided in the pipe 414c. The raw material gas of zinc, the flow rate of which is controlled, is introduced from a gas supply port 418c to the shower head 416 via the pipe 414c. Further, a flow rate of a raw material gas of oxygen supplied from the oxygen source 413d is controlled by a flow rate controller 415d provided in the pipe 414d. The raw material gas of oxygen, the flow rate of which is controlled, is introduced from a gas supply port 418d to the shower head 416 via the pipe 414d. The formed metal oxide film includes one of three elements such as indium, gallium, and zinc, or a plurality of metal elements. Therefore, opening and closing of opening/closing valves (not illustrated) provided in the pipes 414a to 414c are controlled to supply gas of a necessary metal element.

The shower head 416 is provided, for example, at an upper portion of the processing container 411, and has a plurality of discharge holes formed in a lower surface thereof. The shower head 416 discharges the plural kinds of gases introduced via the pipes 414a to 414d in the form of a shower into the processing container 411 via respective discharge holes.

The stage 417 is provided inside the processing container 411. The stage 417 includes a temperature adjustment mechanism (not illustrated). The substrate W on which a film is to be formed is placed on the stage 417. The stage 417 controls a temperature of the substrate W by the temperature adjustment mechanism to a temperature suitable for film formation according to the film forming conditions. In this manner, the first hard mask 105 as the metal oxide film is formed on the front surface of the substrate W.

A controller 900 processes computer-executable commands which cause the film forming apparatus 400 to execute various processes described in the present disclosure. The controller 900 may be configured to control individual constituent elements of the film forming apparatus 400 to execute the various processes described herein.

### [Configuration Example of Etching Apparatus]

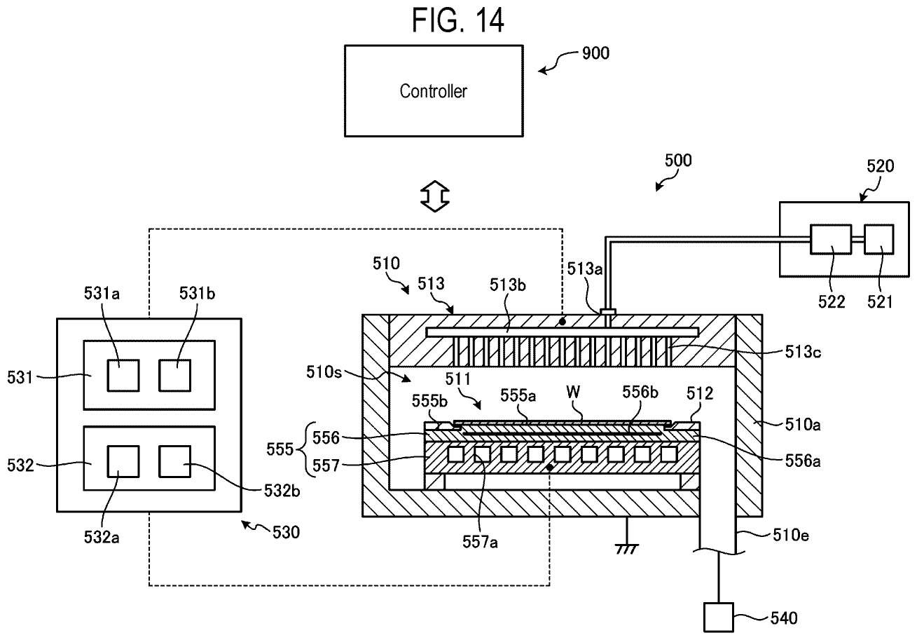

Next, a configuration of the etching apparatus will be described with reference to FIG. 14. FIG. 14 is a view schematically illustrating the configuration of the etching apparatus according to an embodiment. An etching apparatus 500 is used to form the recess 120 corresponding to the first pattern OP in the first hard mask 105 by etching in, for example, Operation G. The etching apparatus 500 may also be used in Operation H of etching the dielectric film, and other etching operations.

The etching apparatus 500 is configured as a capacitively coupled plasma processing apparatus. The etching apparatus 500 is an example of the configuration of the substrate processing apparatus.

The etching apparatus 500 includes a plasma processing chamber (processing container) 510, a gas supply 520, a power source 530, and an exhaust system 540. Further, the etching apparatus 500 includes a substrate support 511 and a gas introducer. The gas introducer is configured to introduce at least one processing gas into the plasma processing chamber 510. The gas introducer includes a shower head 513. The substrate support 511 is disposed inside the plasma processing chamber 510. The shower head 513 is disposed above the substrate support 511. In an embodiment, the shower head 513 constitutes at least a portion of a ceiling of the plasma processing chamber 510. The plasma processing chamber 510 has a plasma processing space 510s defined by the shower head 513, a sidewall 510a of the plasma processing chamber 10, and the substrate support 511. The plasma processing chamber 510 is grounded. The shower head 513 and the substrate support 511 are electrically insulated from a housing of the plasma processing chamber 510.

The substrate support 511 includes a main body 555 and a ring assembly 512. The main body 555 has a central region 555a for supporting the substrate W and an annular region 555b for supporting the ring assembly 512. A wafer is an example of the substrate W. The annular region 555b of the main body 555 surrounds the central region 555a of the main body 555 in a plan view. The substrate W is disposed on the central region 555a of the main body 555, and the ring assembly 512 is disposed on the annular region 555b of the main body 555 to surround the substrate W on the central region 555a of the main body 555. Accordingly, the central region 555a is also referred to as a substrate support surface for supporting the substrate W, and the annular region 555b is also referred to as a ring support surface for supporting the ring assembly 512.

In an embodiment, the main body 555 includes a base 557 and an electrostatic chuck 556. The base 557 includes a conductive member. The conductive member of the base 557 may function as a lower electrode. The electrostatic chuck 556 is disposed on the base 557. The electrostatic chuck 556 includes a ceramic member 556a and an electrostatic electrode 556b disposed in the ceramic member 556a. The ceramic member 556a includes the central region 555a. In an embodiment, the ceramic member 556a also includes the annular region 555b. In addition, another member which surrounds the electrostatic chuck 556, such as an annular electrostatic chuck or an annular insulating member, may include the annular region 555b. In this case, the ring assembly 512 may be disposed on the annular electrostatic chuck or the annular insulating member, or may be disposed on both the electrostatic chuck 556 and the annular insulating member. Further, at least one RF/DC electrode coupled to a radio frequency (RF) power source 531 and/or a direct current (DC) power source 532, which will be described later, may be disposed inside the ceramic member 556a. In this case, the at least one RF/DC electrode functions as the lower electrode. In a case in which a bias RF signal and/or a DC signal, which will be described later, are supplied to the at least one RF/DC electrode, the RF/DC electrode is also referred to as a bias electrode. In addition, the conductive member of the base 557 and the at least one RF/DC electrode may function as a plurality of lower electrodes. Further, the electrostatic electrode 556b may function as the lower electrode. Accordingly, the substrate support 511 includes at least one lower electrode.

The ring assembly 512 includes one or more annular members. In an embodiment, one or more annular members include one or more edge rings and at least one cover ring. The edge ring is made of a conductive material or an insulating material, and the cover ring is made of an insulating material.

In addition, the substrate support 511 may include a temperature adjustment module configured to adjust at least one of the electrostatic chuck 556, the ring assembly 512, or the substrate W to a target temperature. The temperature adjustment module may include a heater, a heat transfer medium, a flow path 557a, or a combination thereof. A heat transfer fluid, such as brine or gas, flows through the flow path 557a. In an embodiment, the flow path 557a is formed inside the base 557, and one or more heaters are arranged inside the ceramic member 556a of the electrostatic chuck 556. Further, the substrate support 511 may include a heat transfer gas supply configured to supply a heat transfer gas to a gap between the rear surface of the substrate W and the central region 555a.

The shower head 513 is configured to introduce at least one processing gas from the gas supply 520 into the plasma processing space 510s. The shower head 513 includes at least one gas supply port 513a, at least one gas diffusion chamber 513b, and a plurality of gas introduction ports 513c. The processing gas supplied to the gas supply port 513a passes through the gas diffusion chamber 513b and is introduced into the plasma processing space 510s via the plurality of gas introduction ports 513c. Further, the shower head 513 includes at least one upper electrode. In addition to the shower head 513, the gas introducer may include one or more side gas injectors (SGIs) provided in one or more openings formed in the sidewall 510a.

The gas supply 520 may include at least one gas source 521 and at least one flow rate controller 522. In an embodiment, the gas supply 520 is configured to supply at least one processing gas from the respective corresponding gas sources 521 to the shower head 513 via the respective flow rate controllers 522. Each flow rate controller 522 may include, for example, a mass flow controller or a pressure-controlled flow rate controller. Further, the gas supply 520 may include at least one flow rate modulation device which modulates or pulses a flow rate of the at least one processing gas.

The power source 530 includes the RF power source 531 coupled to the plasma processing chamber 510 via at least one impedance matching circuit. The RF power source 531 is configured to supply at least one RF signal (RF power) to the at least one lower electrode and/or the at least one upper electrode. Thus, plasma is formed from the at least one processing gas supplied into the plasma processing space 510s. Therefore, the RF power source 531 may function as at least a portion of a plasma generator. Further, by supplying the bias RF signal to the at least one lower electrode, a bias potential may be generated in the substrate W, and ionic components in the formed plasma may be drawn into the substrate W.

In an embodiment, the RF power source 531 includes a first RF generator 531a and a second RF generator 531b. The first RF generator 531a is configured to be coupled to the at least one lower electrode and/or the at least one upper electrode via at least one impedance matching circuit, and is configured to generate a source RF signal (source RF power) for plasma generation. In an embodiment, the source RF signal has a frequency in a range of 10 MHz to 150 MHz. In an embodiment, the first RF generator 531a may be configured to generate a plurality of source RF signals having different frequencies. The one or more source RF signals thus generated are supplied to the at least one lower electrode and/or the at least one upper electrode.

The second RF generator 531b is configured to be coupled to the at least one lower electrode via at least one impedance matching circuit and is configured to generate the bias RF signal (bias RF power). A frequency of the bias RF signal may be equal to or different from that of the source RF signal. In an embodiment, the bias RF signal has a frequency lower than that of the source RF signal. In an embodiment, the bias RF signal has a frequency in a range of 100 kHz to 60 MHz. In an embodiment, the second RF generator 531b may be configured to generate a plurality of bias RF signals having different frequencies. The one or more bias RF signals thus generated are supplied to the at least one lower electrode. In addition, in various embodiments, at least one of the source RF signal or the bias RF signal may be pulsed.

In addition, the power source 530 may include a DC power source 32 coupled to the plasma processing chamber 510. The DC power source 532 includes a first DC generator 532a and a second DC generator 532b. In an embodiment, the first DC generator 532a is configured to be connected to the at least one lower electrode to generate a first DC signal. The generated first DC signal is applied to the at least one lower electrode. In an embodiment, the second DC generator 532b is configured to be connected to the at least one upper electrode to generate a second DC signal. The generated second DC signal is applied to the at least one upper electrode.

In various embodiments, the first and second DC signals may be pulsed. In this case, a sequence of voltage pulses is applied to the at least one lower electrode and/or the at least one upper electrode. The voltage pulse may have a pulse waveform of a rectangle, a trapezoid, a triangle or a combination thereof. In an embodiment, a waveform generator (not illustrated) for generating the sequence of voltage pulses from the DC signal is connected between the first DC generator 532a and the at least one lower electrode. Accordingly, the first DC generator 532a and the waveform generator constitute a voltage pulse generator. In the case in which the second DC generator 532b and the waveform generator constitute the voltage pulse generator, the voltage pulse generator is connected to the at least one upper electrode. The voltage pulse may have a positive polarity or a negative polarity. In addition, the sequence of the voltage pulses may include one or more positive voltage pulses and one or more negative voltage pulses in one cycle. In addition, the first and second DC generators 532a and 532b may be provided in addition to the RF power source 531, and the first DC generator 532a may be provided instead of the second RF generator 531b.

During plasma processing, the etching apparatus 500 supplies the source RF signal from the first RF generator 531a to the upper electrode of the shower head 513, the lower electrode of the base 557 constituting the substrate support 511, or the lower electrode provided in the electrostatic chuck 556. Further, during the plasma processing, the etching apparatus 500 applies the pulsed first DC signal from the first DC generator 532a to the lower electrode of the base 557. During the plasma processing, the etching apparatus 500 may apply the second DC signal from the second DC generator 532b to the upper electrode of the shower head 513. The first DC generator 532a is capable of changing a duty ratio during one cycle in the pulsed first DC signal. For example, the first DC generator 532a is capable of changing a ratio of a period in which the first DC signal during one cycle is turned on.

The exhaust system 540 may be connected to, for example, a gas exhaust port 510e provided at a bottom portion of the plasma processing chamber 510. The exhaust system 540 may include a pressure adjusting valve and a vacuum pump. By the pressure adjusting valve, an internal pressure of the plasma processing space 510s is adjusted. The vacuum pump may include a turbo molecular pump, a dry pump, or a combination thereof.

A controller 900 processes computer-executable commands which cause the etching apparatus 500 to execute various processes described in the present disclosure. The controller 900 may be configured to control individual constituent elements of the substrate processing apparatus to execute the various processes described herein.

Operations of the etching apparatus 500 configured as above are comprehensively controlled by the controller 900. The controller 900 controls plasma etching. For example, the controller 900 controls the exhaust system 540 to exhaust an interior of the plasma processing chamber 510 to a predetermined level of vacuum. The controller 900 controls the gas supply 520 to introduce a processing gas for etching from the gas supply 520 into the plasma processing space 510s. The controller 900 controls the power source 530 to supply power in parallel with the introduction of the processing gas so that plasma is generated inside the plasma processing chamber 510 to etch the substrate W.

### [Configuration Example of Cleaning Apparatus]

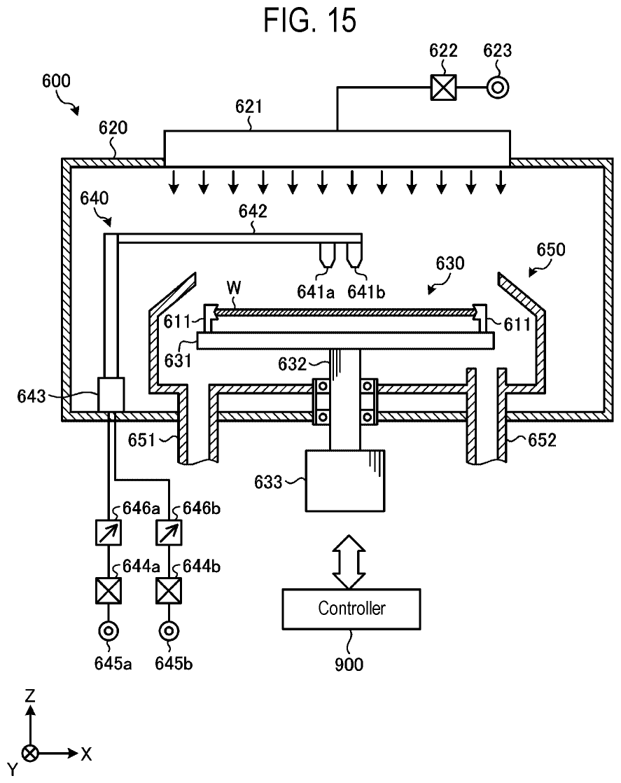

Next, an example of a configuration of the cleaning apparatus will be described with reference to FIG. 15. FIG. 15 is a view schematically illustrating the configuration of the cleaning apparatus according to an embodiment. A cleaning apparatus 600 removes the first hard mask 105 by cleaning the substrate W in, for example, Operation I. The cleaning apparatus 600 may also be used to perform other cleaning operations. The cleaning apparatus 600 is an example of the configuration of the substrate processing apparatus.

As illustrated in FIG. 15, the cleaning apparatus 600 includes a processing container 620, a substrate holding mechanism 630, a liquid supply 640, and a collection cup 650. The processing container 620 accommodates the substrate holding mechanism 630, the liquid supply 640, and the collection cup 650. A fan filter unit (FFU) 621 is provided at a ceiling of the processing container 620. The FFU 621 forms down-flow inside the processing container 620.

The FFU 621 is connected to a down-flow gas source 623 via a valve 622. The FFU 621 discharges a down-flow gas (e.g., dry air) supplied from the down-flow gas source 623 into the processing container 620.

The substrate holding mechanism 630 includes a rotary holder 631, a columnar support 632, and a driver 633. The rotary holder 631 is provided substantially at the center of the processing container 620. A holding member 611 is provided on an upper surface of the rotary holder 631 to laterally hold the substrate W. The substrate W is held horizontally in a state in which the substrate W is slightly spaced apart from the upper surface of the rotary holder 631 by the holding member 611.

The columnar support 632 is a member which extends vertically, and a base end thereof is rotatably supported by the driver 633. The columnar support 632 supports the rotary holder 631 horizontally at a leading end thereof. The driver 633 rotates the columnar support 632 around a vertical axis.

The substrate holding mechanism 630 rotates the rotary holder 631 supported by the columnar support 632 by rotating the columnar support 632 using the driver 633. As a result, the substrate W held by the rotary holder 631 is rotated.

In addition, the rotary holder 631 is not limited to a type of laterally holding the substrate W as described above, and may be of, for example, a type of attractively holding the substrate W from below, such as a vacuum chuck.

The liquid supply 640 supplies various kinds of processing liquids to the substrate W held by the substrate holding mechanism 630. The liquid supply 640 includes a plurality (two in this embodiment) of nozzles 641a and 641b, an arm 642 which horizontally supports the nozzles 641a and 641b, and a swiveling/lifting mechanism 643 which swivels and lifts the arm 642. Further, the nozzle 641a and the nozzle 641b may be supported by respective arms. The nozzle 641a is an example of a liquid supply port which supports a cleaning liquid. The nozzle 641b is an example of a liquid supply port which supplies a rinsing liquid.

The nozzle 641a is connected to a cleaning chemical-liquid source 645a via a valve 644a and a flow rate adjuster 646a. Further, the nozzle 641b is connected to a rinsing liquid source 645b via a valve 644b and a flow rate adjuster 646b.

A cleaning chemical-liquid, such as DHF, HPM, or APM, which is supplied from the cleaning chemical-liquid source 645a, is discharged from the nozzle 641a. A rinsing liquid supplied from the rinsing liquid source 645b is discharged from the nozzle 641b. The rinsing liquid is, for example, deionized water (DIW). DHF, HPM, or APM is an example of the cleaning liquid.

The collection cup 650 is disposed to surround the rotary holder 631 and collects the processing liquid scattered from the substrate W with the rotation of the rotary holder 631. A liquid discharge port 651 is formed in a bottom portion of the collection cup 650. The processing liquid collected by the collection cup 650 is discharged from the liquid discharge port 651 outward of the cleaning apparatus 600. Further, an exhaust port 652 is formed in the bottom portion of the collection cup 650 to exhaust the down-flow gas supplied from the FFU 621 outward of the cleaning apparatus 600.

In addition, the number of nozzles provided in the cleaning apparatus 600 is not limited to the above-described example. For example, the cleaning apparatus 600 may be configured to include a single nozzle which discharges the cleaning chemical-liquid and the rinsing liquid.

A controller 900 processes computer-executable commands which cause the cleaning apparatus 600 to execute various processes described in the present disclosure. The controller 900 may be configured to control individual constituent elements of the cleaning apparatus 600 to execute the various processes described herein.

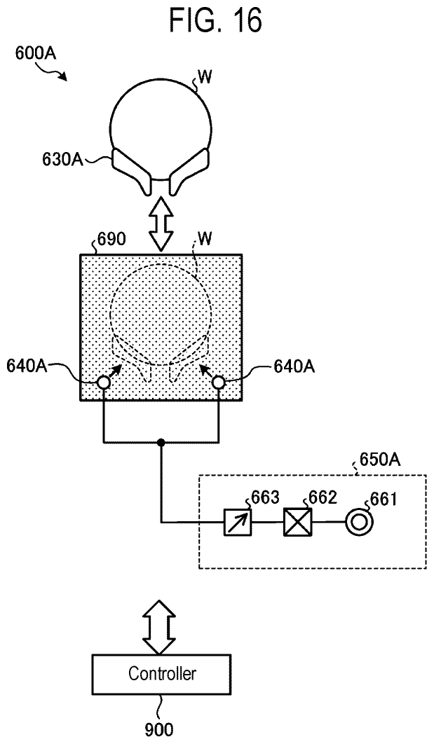

In the above-described embodiment, an example in which the cleaning chemical-liquid is used in the cleaning apparatus 600 which performs a single-wafer-type wet etching process (hereinafter, simply referred to as an “etching process”) has been described. However, the cleaning chemical-liquid may be used for a batch-type etching process which collectively processes a plurality of substrates W. An example of a cleaning apparatus 600A which performs the batch-type etching process will be described later with reference to FIG. 16. FIG. 16 is a view illustrating a configuration of a cleaning apparatus according to a modification. The cleaning apparatus 600A is an example of the configuration of the substrate processing apparatus.

As illustrated in FIG. 16, a cleaning chemical-liquid supply system 650A according to the modification includes a cleaning chemical-liquid source 661, a valve 662, and a flow rate adjuster 663. The cleaning apparatus 600A according to the modification includes a processing tank 690, a substrate holding mechanism 630A, and a liquid supply 640A.

The processing tank 690 stores a cleaning chemical-liquid. The substrate holding mechanism 630A collectively holds the plurality of substrates W in a vertical posture. The substrate holding mechanism 630A is capable of being raised and lowered by a lifting mechanism (not illustrated). The liquid supply 640A is connected to the cleaning chemical-liquid supply 661 via the valve 662 and the flow rate adjuster 663 and supplies the cleaning chemical-liquid to the processing tank 690. Thus, the cleaning chemical-liquid is stored in the processing tank 690.

A controller 900 processes computer-executable commands which cause the cleaning apparatus 600A to execute various processes described in the present disclosure. The controller 900 may be configured to control individual constituent elements of the cleaning apparatus 600A to execute the various processes described herein.

In the processing according to the modification, by lowering the substrate holding mechanism 630A, the plurality of substrates W held by the substrate holding mechanism 630A are immersed in the cleaning chemical-liquid stored in the processing tank 690. Thus, the first hard mask 105 formed on the front surface of the substrate W is removed. As described above, the cleaning chemical-liquid may also be applied to the batch-type etching process in which the plurality of substrates W are collectively processed.

### [Configuration Example of Substrate Processing System]

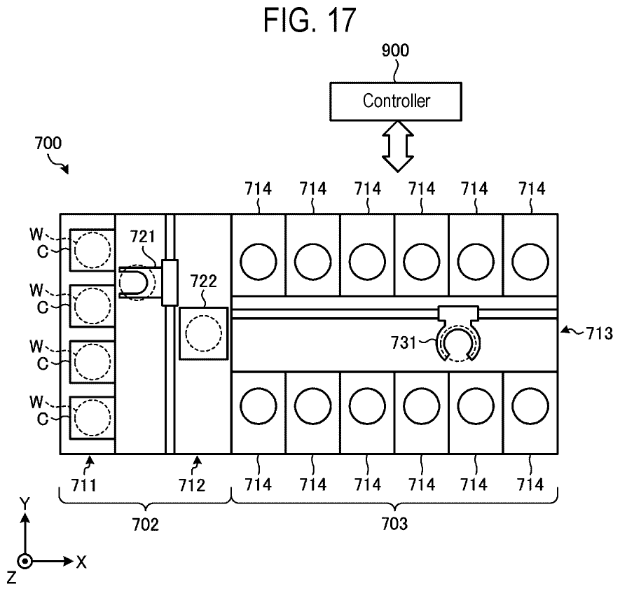

A substrate processing system according to an embodiment will be described with reference to FIG. 17. FIG. 17 is a view schematically illustrating a configuration of the substrate processing system according to an embodiment. Further, for clarification of a positional relationship, an X-axis direction, a Y-axis direction, and a Z-axis direction, which are orthogonal to one another, are defined in the following description, and a positive Z-axis direction is defined as a vertical upward direction.

A substrate processing system 700 includes a loading/unloading station 702 and a processing station 703. The loading/unloading station 702 and the processing station 703 are provided to be adjacent to each other.

The loading/unloading station 702 includes a carrier stage 711 and a transferer 712. A plurality of transfer containers (hereinafter, referred to as “carriers C”), which are capable of accommodating the plurality of substrates W horizontally, are placed on the carrier stage 711.

The transferer 712 is provided to be adjacent to the carrier stage 711. A substrate transfer device 721 and a delivery part 722 are provided inside the transferer 712.

The substrate transfer device 721 includes a wafer holding mechanism which holds the substrate W. Further, the substrate transfer device 721 is movable horizontally and vertically and swingable around a vertical axis, and transfers the substrate W between the carrier C and the delivery part 722 using the wafer holding mechanism.

The processing station 703 is provided to be adjacent to the transferer 712. The processing station 703 includes a transferer 713 and a plurality of substrate processing apparatuses 714. The plurality of substrate processing apparatuses 714 are provided side by side at both sides of the transfer unit 713.

The transferer 713 includes a substrate transfer device 731 provided therein. The substrate transfer device 731 includes a wafer holding mechanism which holds the substrate W. Further, the substrate transfer device 731 is movable horizontally and vertically and swingable around a vertical axis, and performs transfer of the substrate W between the delivery part 722 and the substrate processing apparatus 714 using the wafer holding mechanism.

One of the substrate processing apparatuses 714 may be the cleaning apparatus 600 shown in FIG. 15. One of the substrate processing apparatuses 714 may be the cleaning apparatus 600A shown in FIG. 16. The substrate processing apparatus 71 as the cleaning apparatus 600 (or 600A) performs the etching process. The etching process may be performed to remove, for example, the metal oxide film constituting the first hard mask 105 disposed on the dielectric film 103.

In the substrate processing system 700 configured as above, first, the substrate transfer device 721 of the loading/unloading station 702 takes out the substrate W from the carrier C, and places the taken-out substrate W on the delivery part 722. The substrate W placed on the delivery part 722 is taken out from the delivery part 722 by the substrate transfer device 731 of the processing station 703 and is loaded into the substrate processing apparatus 714 as the cleaning apparatus 600 (or 600A) where the etching process is performed. The substrate W subjected to the etching process is unloaded from the substrate processing apparatus 714 by the substrate transfer device 731, placed on the delivery part 722, and then returned to the carrier C by the substrate transfer device 721.

The substrate processing system 700 includes a controller 900. The controller 900 is a device for controlling an operation of the substrate processing system 700. The substrate transfer device 731 may be controlled to be kept in a vacuum atmosphere. Accordingly, one of the substrate processing apparatuses 714 may be the film forming apparatus 300 kept in the vacuum atmosphere, which is shown in FIG. 12. Further, one of the substrate processing apparatuses 714 may be the film forming apparatus 400 kept in the vacuum atmosphere, which is shown in FIG. 13. Further, one of the substrate processing apparatuses 714 may be the etching apparatus 500 kept in the vacuum atmosphere, which is shown in FIG. 14. Accordingly, in the substrate processing system 700, it is possible to comprehensively perform the operations of the substrate processing method according to the first embodiment and the substrate processing method according to the second embodiment.

According to the present disclosure in some embodiments, it is possible to reduce roughness of a wiring.

In addition, it should be noted that the embodiments disclosed herein are exemplary in all respects and are not restrictive. Indeed, the above-described embodiments may be implemented in various forms. Further, the above-described embodiments may be omitted, replaced, and/or modified in various forms without departing from the scope and spirit of the appended claims.

In addition, with respect to the above-described embodiments, the following supplementary notes are further provided.

### Supplementary Note 1

A substrate processing method includes:
an operation (A) of providing a substrate having a first surface and a second surface opposite the first surface;
an operation (B) of forming a dielectric film on the first surface;
an operation (C) of forming a metal oxide film as a first hard mask including one or two or more metal elements with a predetermined composition on the dielectric film, wherein the metal oxide film includes no crystalline film;
after the operation (C), an operation (F) of forming a resist-related first film in which a first pattern is formed;
after the operation (F), an operation (G) of etching the first hard mask to form a recess corresponding to the first pattern in the first hard mask;
an operation (H) of etching the dielectric film to form the recess corresponding to the first pattern in the dielectric film;
after the operation (H), an operation (I) of cleaning the substrate to remove the first hard mask;
an operation (J) of embedding a metal in the recess formed in the dielectric film; and
an operation (K) of planarizing the metal.

### Supplementary Note 2

In the substrate processing method of Supplementary Note 1 above, the one or two or more metal elements include at least one of indium, gallium or zinc.

### Supplementary Note 3

In the substrate processing method of Supplementary Note 1 or 2 above, the one or two or more metal elements include at least one of indium or gallium, and zinc, and a composition ratio of the zinc with respect to an entirety of the one or two or more metal elements is 80% or less.

### Supplementary Note 4

In the substrate processing method of any one of Supplementary Notes 1 to 3 above, the metal oxide film is a crystalline film.

### Supplementary Note 5

The substrate processing method of any one of Supplementary Notes 1 to 4 above further includes: after the operation (C), an operation (D) of cleaning the second surface and an outer peripheral portion of the first surface.

### Supplementary Note 6

The substrate processing method of Supplementary Note 5 above further includes: after the operation (D), an operation (E) of forming a silicon-containing film as a second hard mask, and
the operation (G) includes etching the first hard mask and the second hard mask to form the recess corresponding to the first pattern in the first hard mask.

### Supplementary Note 7

In the substrate processing method of Supplementary Note 6 above, the operation (F) includes:
an operation of forming the first film on the second hard mask;
an operation of forming the first pattern in the first film by exposure and development; and
an operation of etching the second hard mask to form the recess corresponding to the first pattern in the second hard mask.

### Supplementary Note 8

In the substrate processing method of any one of Supplementary Notes 1 to 7 above, the operation (G) includes forming the recess in the first hard mask by a gas capable of generating CH₃ radicals.

### Supplementary Note 9

In the substrate processing method of any one of Supplementary Notes 1 to 8 above, in the operation (C),
the metal oxide film includes indium, gallium, zinc, and oxygen at a composition ratio of 1:1:1:4,
a temperature of a stage on which the substrate is placed is 25 degrees C. to 400 degrees C., and
a bias power value supplied to the stage is 800 W to 1,400 W.

### Supplementary Note 10

The substrate processing method of Supplementary Note 6 above further includes:
after the operation (G), an operation (L) of forming a resist-related second film in which a second pattern is formed;
after the operation (L), an operation (M) of etching the dielectric film to form a via corresponding to the second pattern in the dielectric film; and
after the operation (M), an operation (N) of ashing the second film,
wherein the operation (H) includes forming the via penetrating through the dielectric film after the operation (N), and
wherein the operation (J) includes embedding the metal in the recess and the via formed in the dielectric film.

### Supplementary Note 11

In the substrate processing method of Supplementary Note 10 above, the operation (L) includes:
an operation of forming the second film on the second hard mask; and
an operation of forming the second pattern in the second film by exposure and development.

### Supplementary Note 12

In the substrate processing method of any one of Supplementary Notes 1 to 11 above, the operation (I) includes:
an operation of cleaning the substrate with acid;
an operation of cleaning the substrate with alkali; and
an operation of rinsing the substrate with a rinsing liquid.

### Supplementary Note 13

In the substrate processing method of Supplementary Note 12 above, in the operation (I), in terms of a flatness of the recess of the dielectric film after removing the first hard mask, a line-edge roughness is 1.6 nm or less and a line-width roughness is 1.2 nm or less.

### Supplementary Note 14

A substrate processing apparatus includes:
a processing container;
a gas supply port; and
a controller,
wherein the controller controls:
   loading a substrate on which a dielectric film is formed into the processing container; and
   forming, on the dielectric film, a metal oxide film as a first hard mask including one or two or more metal elements with a predetermined composition, by a gas including the one or two or more metal elements, which are supplied from the gas supply port, wherein the metal oxide film includes no crystalline film.

### Supplementary Note 15

A substrate processing apparatus includes:
a processing container;
a gas supply port; and
a controller,
wherein the controller controls:
   loading, into the processing container, a substrate in which a first hard mask and a resist-related first film on which a first pattern is formed are sequentially formed on a dielectric film; and
   etching the first hard mask by a gas capable of generating CH₃ radicals, which is supplied from the gas supply port, and forming, in the first hard mask, a recess corresponding to the first pattern formed in the resist-related first film.

### Supplementary Note 16

A substrate processing apparatus includes:
a processing container;
a liquid supply port; and
a controller,
wherein the controller controls:
   loading, into the processing container, a substrate on which a dielectric film in which a recess is formed and a first hard mask are sequentially formed; and
   supplying a cleaning liquid and a rinsing liquid from the liquid supply port to clean the substrate with acid, clean the substrate with alkali, rinse the substrate with the rinsing liquid, and remove the first hard mask.

What is claimed is:

1. A substrate processing method, comprising:
an operation (A) of providing a substrate having a first surface and a second surface opposite the first surface;
an operation (B) of forming a dielectric film on the first surface;
an operation (C) of forming a metal oxide film as a first hard mask including one or two or more metal elements with a predetermined composition on the dielectric film, wherein the metal oxide film includes no crystalline film;
after the operation (C), an operation (F) of forming a resist-related first film in which a first pattern is formed;
after the operation (F), an operation (G) of etching the first hard mask to form a recess corresponding to the first pattern in the first hard mask;
an operation (H) of etching the dielectric film to form the recess corresponding to the first pattern in the dielectric film;
after the operation (H), an operation (I) of cleaning the substrate to remove the first hard mask;
an operation (J) of embedding a metal in the recess formed in the dielectric film; and
an operation (K) of planarizing the metal.

2. The substrate processing method of claim 1, wherein the one or two or more metal elements include at least one of indium, gallium, or zinc.

3. The substrate processing method of claim 2, wherein the one or two or more metal elements include at least one of indium or gallium, and zinc, and a composition ratio of the zinc with respect to an entirety of the one or two or more metal elements is 80% or less.

4. The substrate processing method of claim 1, wherein the metal oxide film is a crystalline film.

5. The substrate processing method of claim 1, further comprising: after the operation (C), an operation (D) of cleaning the second surface and an outer peripheral portion of the first surface.

6. The substrate processing method of claim 5, further comprising: after the operation (D), an operation (E) of forming a silicon-containing film as a second hard mask, wherein the operation (G) includes etching the first hard mask and the second hard mask to form the recess corresponding to the first pattern in the first hard mask.

7. The substrate processing method of claim 6, wherein the operation (F) includes:
an operation of forming the first film on the second hard mask;
an operation of forming the first pattern in the first film by exposure and development; and
an operation of etching the second hard mask to form the recess corresponding to the first pattern in the second hard mask.

8. The substrate processing method of claim 1, wherein the operation (G) includes forming the recess in the first hard mask by a gas capable of generating CH₃ radicals.

9. The substrate processing method of claim 1, wherein, in the operation (C),
the metal oxide film includes indium, gallium, zinc, and oxygen at a composition ratio of 1:1:1:4,
a temperature of a stage on which the substrate is placed is 25 degrees C. to 400 degrees C., and
a bias power value supplied to the stage is 800 W to 1,400 W.

10. The substrate processing method of claim 6, further comprising:
after the operation (G), an operation (L) of forming a resist-related second film in which a second pattern is formed;
after the operation (L), an operation (M) of etching the dielectric film to form a via corresponding to the second pattern in the dielectric film; and
after the operation (M), an operation (N) of ashing the second film,
wherein the operation (H) includes forming the via penetrating through the dielectric film after the operation (N), and
wherein the operation (J) includes embedding the metal in the recess and the via formed in the dielectric film.

11. The substrate processing method of claim 10, wherein the operation (L) includes:
an operation of forming the second film on the second hard mask; and
an operation of forming the second pattern in the second film by exposure and development.

12. The substrate processing method of claim 1, wherein the operation (I) includes:
an operation of cleaning the substrate with acid;
an operation of cleaning the substrate with alkali; and
an operation of rinsing the substrate with a rinsing liquid.

13. The substrate processing method of claim 12, wherein, in the operation (I), in terms of a flatness of the recess of the dielectric film after removing the first hard mask, a line-edge roughness is 1.6 nm or less and a line-width roughness is 1.2 nm or less.

14. A substrate processing apparatus, comprising:
a processing container;
a gas supply port; and
a controller,
wherein the controller controls:
loading a substrate on which a dielectric film is formed into the processing container; and
forming, on the dielectric film, a metal oxide film as a first hard mask including one or two or more metal elements with a predetermined composition, by a gas including the one or two or more metal elements, which are supplied from the gas supply port, wherein the metal oxide film includes no crystalline film.

15. A substrate processing apparatus, comprising:
a processing container;
a gas supply port; and
a controller,
wherein the controller controls:
loading, into the processing container, a substrate in which a first hard mask and a resist-related first film on which a first pattern is formed are sequentially formed on a dielectric film; and
etching the first hard mask by a gas capable of generating CH₃ radicals, which is supplied from the gas supply port, and forming, in the first hard mask, a recess corresponding to the first pattern formed in the resist-related first film.

16. A substrate processing apparatus, comprising:
a processing container;
a liquid supply port; and
a controller,
wherein the controller controls:
loading, into the processing container, a substrate on which a dielectric film in which a recess is formed and a first hard mask are sequentially formed; and
supplying a cleaning liquid and a rinsing liquid from the liquid supply port to clean the substrate with acid, clean the substrate with alkali, rinse the substrate with the rinsing liquid, and remove the first hard mask.
